(19) United States
(12) Patent Application Publication
(10) Pub. No.: US 2016/0148888 A1
(43) Pub. Date: May 26, 2016

(54) SEMICONDUCTOR DEVICES AND METHODS FOR FABRICATING THE SAME

(71) Applicants: Seung-Kwan RYU, Seongnam-si (KR); Jongbo SHIM, Asan-si (KR); Eunchul AHN, Seoul (KR); Taeje CHO, Yongin-si (KR)

(72) Inventors: Seung-Kwan RYU, Seongnam-si (KR); Jongbo SHIM, Asan-si (KR); Eunchul AHN, Seoul (KR); Taeje CHO, Yongin-si (KR)

(21) Appl. No.: 14/948,228

(22) Filed: Nov. 20, 2015

(30) Foreign Application Priority Data
Nov. 20, 2014 (KR) 10-2014-0162642
Dec. 11, 2014 (KR) 10-2014-0178256

(51) Int. Cl. H01L 23/00; H01L 23/48

(52) U.S. Cl. CPC H01L 24/14; H01L 24/06; H01L 23/481; H01L 2224/0401; H01L 2224/0603; H01L 2224/06051; H01L 2224/06102; H01L 2224/14051; H01L 2224/14104; H01L 2224/14183; H01L 2224/145; H01L 2924/01028; H01L 2924/01029; H01L 2924/01079

(57) ABSTRACT

A semiconductor device may include a semiconductor substrate, a conductive pad on the semiconductor substrate, a passivation layer overlying the semiconductor substrate and exposing the conductive pad, and a bump structure. The bump structure may include a first bump structure on the conductive pad and a second bump structure on the passivation layer. The first bump structure may include a base bump layer, a first pillar bump layer, and a first solder bump layer that are sequentially stacked on the conductive pad. The second bump structure may include a second pillar bump layer and a second solder bump layer that are sequentially stacked on the passivation layer.

### CROSS-REFERENCE TO RELATED APPLICATIONS

This application claims priority under 35 U.S.C. §119 of Korean Patent Application 10-2014-0162642 filed on Nov. 20, 2014, and Korean Patent Application 10-2014-0178256 filed on Dec. 11, 2014, the entire contents of which are hereby incorporated by reference.

### BACKGROUND

The present inventive concept relates to semiconductor devices and methods for fabricating the same.

Recently, as a semiconductor device has become lighter, thinner, and smaller, an external terminal that connects the semiconductor device to a package substrate or another semiconductor device is also being reduced in size. Stable implementation of the external terminal helps achieve a reliable semiconductor package including a semiconductor device. Accordingly, in order to improve the reliability of an external terminal, various studies are being conducted.

### SUMMARY

According to example embodiments of the inventive concepts, a semiconductor device may comprise a semiconductor substrate, a conductive pad disposed on the semiconductor substrate, a passivation layer disposed on the semiconductor substrate and including an opening exposing the conductive pad, a first under bump metal (UBM) layer disposed on the exposed conductive pad, a second under bump metal (UBM) layer disposed on the passivation layer, a first bump structure disposed on the first UBM layer, and a second bump structure disposed on the second UBM layer. The first bump structure may include a base bump layer, a first pillar bump layer, and a first solder bump layer that are sequentially stacked on the first UBM layer, and a second bump structure may include a second pillar bump layer and a second solder bump layer that are sequentially stacked on the second UBM layer.

In some example embodiments, each of horizontal widths of the opening and the base bump layer may be greater than a horizontal width of the first pillar bump.

In some example embodiments, the base bump layer may comprise a base portion underneath the first pillar bump layer and a protrusion portion spaced apart from the first pillar bump layer.

In some example embodiments, the base portion may fill at least a portion of the opening.

In some example embodiments, the protrusion portion may be disposed adjacent to an inner sidewall of the opening and surround the first pillar bump layer.

In some example embodiments, the protrusion portion may comprise a sloped inner sidewall opposed to a sidewall of the first pillar bump layer, and may extend along a top surface of the first UBM layer in a direction away from a center of the opening, wherein an area of the base bump layer is no less than an area of the conductive pad in plan view.

In some example embodiments, the first pillar bump layer may have a thickness substantially identical to that of the second pillar bump layer.

In some example embodiments, a top end of the first bump structure and a top end of the second bump structure may be positioned at substantially the same level relative to a main surface of the semiconductor substrate.

In some example embodiments, the first and second pillar bump layers may include a same metal, and the first and second solder bump layers may include a same solder material.

In some example embodiments, a horizontal width of the first pillar bump layer may be greater than that of the second pillar bump layer.

In some example embodiments, the first pillar bump layer may have a shape different from the second pillar bump layer, in plan view.

In some example embodiments, each of the base bump layer and the first pillar bump layer may include Cu, Cu alloy, Ni, Ni alloy, Au, Au alloy, or combinations thereof.

In some example embodiments, the semiconductor device may further comprise at least one through-substrate via (TSV) penetrating the semiconductor substrate and connected to the conductive pad. According to example embodiments of the inventive concepts, a semiconductor device may comprise a conductive pad disposed on a semiconductor substrate, a passivation layer disposed on the semiconductor substrate and including an opening exposing the conductive pad, an under bump metal (UBM) layer disposed on the conductive pad and in the opening, at least one bump structure including a base bump layer, a pillar bump layer, and a solder bump layer sequentially stacked on the UBM layer. The base bump layer may be disposed on the UBM layer and may include a base portion filling at least a portion of the opening and a protrusion portion extending upwardly from the base portion. The pillar bump layer may be disposed on the base portion and spaced apart from the protrusion portion, and the solder bump layer may be disposed on the pillar bump layer.

In some example embodiments, each of horizontal widths of the opening and the base bump layer may be greater than a horizontal width of the pillar bump layer.

In some example embodiments, the protrusion portion may be disposed adjacent to an inner sidewall of the opening and may surround a portion of the pillar bump layer.

In some example embodiments, the protrusion portion may comprise a sloped inner sidewall opposed to a sidewall of the pillar bump layer and may extend along a top surface of the UBM layer away from a center of the opening.

In some example embodiments, the semiconductor device may further comprise a second bump structure spaced away from the first bump structure. The second bump structure may be substantially identical to the first bump structure, and a top end of the first bump structure and a top end of the second bump structure are at a same level relative to a main surface of the semiconductor substrate.

According to example embodiments of the inventive concepts, a semiconductor device may comprise a semiconductor substrate including a first region and a second region, a conductive pad disposed on the first region of the semiconductor substrate, a passivation layer disposed on the first and second regions of the semiconductor substrate and including an opening exposing the conductive pad, a first bump structure disposed on the first region to be electrically connected to the conductive pad and including a base bump layer, a first pillar bump layer, and a first solder bump layer that are sequentially stacked on the conductive pad, and a second bump structure disposed on the second region, being isolated from the conductive pad, and including a second pillar bump layer and a second solder bump layer that are sequentially stacked on the passivation layer. The base bump layer may comprise a base portion disposed underneath the first pillar bump layer and covering the conductive pad, and a protrusion portion being adjacent to an inner sidewall of the opening and spaced apart from the pillar bump layer.

In some example embodiments, the semiconductor device may further comprise at least one through-substrate via (TSV) penetrating the semiconductor substrate and connected to the conductive pad, wherein the first region is a central region of the semiconductor substrate, and the second region is a peripheral region of the semiconductor substrate.

In some example embodiments, each of horizontal widths of the opening and the base bump layer may be greater than a horizontal width of the first pillar bump layer.

In some example embodiments, the protrusion portion may surround a portion of the first pillar bump layer, a thickness of the base portion may be configured to supplement a step difference between a top surface of the conductive pad and a top surface of the passivation layer such that a top end of the first bump structure and a top end of the second bump structure are at substantially a same level relative to a main surface of the semiconductor substrate.

According to example embodiments of the inventive concepts, a semiconductor package may comprise a package substrate including first and second substrate pads disposed thereon, and a semiconductor device mounted on the package substrate. The semiconductor device may comprise a semiconductor substrate, a conductive pad on the semiconductor substrate, a passivation layer on the semiconductor substrate with an opening exposing the conductive pad, a first bump structure coupled to the first substrate pad of the package substrate, and a second bump structure coupled to the second substrate pad of the package substrate. The first bump structure may comprise a base bump layer, a first pillar bump layer, and a first solder bump layer that are sequentially stacked on the conductive pad. The second bump structure may comprise a second pillar bump layer and a second solder bump layer that are sequentially stacked on the passivation layer.

According to example embodiments of the inventive concepts, a semiconductor package may comprise a package substrate including a substrate pad, and a semiconductor device mounted on the package substrate. The semiconductor device may comprise a semiconductor substrate, a conductive pad on the semiconductor substrate, a passivation layer disposed on the semiconductor substrate and including an opening exposing the conductive pad, a under bump metal (UBM) layer disposed on the conductive pad and in the opening, a base bump layer disposed on the UBM layer and including a base portion filling at least a portion of the opening, and a protrusion portion extending upwardly from the base portion, a pillar bump layer disposed on the base portion and spaced apart from the protrusion portion, a solder bump layer disposed on the pillar bump layer and bonded to the substrate pad of the package substrate.

According to example embodiments of the inventive concepts, a method for fabricating a semiconductor device may comprise forming a conductive pad on a semiconductor substrate, forming a passivation layer on the semiconductor substrate with a first opening exposing the conductive pad, forming an under bump metal (UBM) layer on the passivation layer and the conductive pad, forming a base bump layer on the UBM layer on the conductive pad to fill at least a portion of the first opening, forming a first pillar bump layer on the base bump layer, forming a second pillar bump layer on the UBM layer disposed on the passivation layer, and forming a first solder bump layer on the first pillar bump layer and a second solder bump layer on the second pillar bump layer.

According to example embodiments of the inventive concepts, a method for fabricating a semiconductor device may comprise forming a conductive pad on a semiconductor substrate, forming a passivation layer on the semiconductor substrate with an opening exposing the conductive pad, forming an under bump metal (UBM) layer on the conductive pad and in the opening, forming a base bump layer on the UBM layer with a base portion filling at least a portion of the opening and a protrusion portion extending upwardly from the base portion, forming a pillar bump layer on the base portion to be spaced apart from the protrusion portion, and forming a solder bump layer on the pillar bump layer.

### BRIEF DESCRIPTION OF THE DRAWINGS

The foregoing and other features and advantages of example embodiments of inventive concepts will be apparent from the more particular description of non-limiting embodiments of inventive concepts, as illustrated in the accompanying drawings in which like reference characters refer to the same parts throughout the different views. The drawings are not necessarily to scale, emphasis instead being placed upon illustrating the principles of inventive concepts. In the drawings:

FIG. 1A is a cross-sectional view illustrating a semiconductor device according to some example embodiments of the inventive concepts;

FIG. 1B is an enlarged cross-sectional view illustrating a portion OA of FIG. 1A;

FIG. 1C and FIG. 1D are plan views illustrating a bump structure as shown in FIG. 1B, respectively;

FIG. 1E and FIG. 1F are cross-sectional views illustrating a portion of an integrated circuit layer as shown in FIG. 1A, respectively;

FIG. 2A is a cross-sectional view illustrating a semiconductor package including a semiconductor device according to some example embodiments of the inventive concepts;

FIG. 2B is an enlarged cross-sectional view illustrating a portion PA of FIG. 2A;

FIGS. 2C and 2D are cross-sectional views illustrating methods for forming an interconnection between a bump structure of the semiconductor device and a package substrate;

FIG. 3A is a cross-sectional view illustrating a semiconductor device according to some example embodiments of the inventive concepts;

FIG. 3B is an enlarged cross-sectional view illustrating a portion OB of FIG. 3A;

FIG. 3C is a plan view illustrating a bump structure as shown in FIG. 3B;

FIG. 4A is a cross-sectional view illustrating a semiconductor package including a semiconductor device according to some example embodiments of the inventive concepts;

FIG. 4B is an enlarged cross-sectional view illustrating a portion PB of FIG. 4A;

FIGS. 5A to 5F are cross-sectional views illustrating a method for fabricating a semiconductor device according to some example embodiments of the inventive concepts;

FIGS. 6A to 6e are cross-sectional views illustrating a method for fabricating a semiconductor device according to some example embodiments of the inventive concepts;

FIGS. 7 is a schematic block diagram illustrating an example of memory module including at least one of the semiconductor devices and/or the semiconductor packages according to some example embodiments of the inventive concepts;

FIG. 8 is a schematic block diagram illustrating an example of memory system including at least one of the semiconductor devices and/or the semiconductor packages according to example embodiments of the inventive concepts; and

FIG. 9 is a schematic block diagram illustrating an example of an electronic system including at least one of the semiconductor devices and/or the semiconductor packages according to example embodiments of the inventive concepts.

### DETAILED DESCRIPTION

The example embodiments of the present disclosure will now be described more fully hereinafter with reference to the accompanying drawings, in which example embodiments of the inventive concepts are shown. The advantages and features of the example embodiments of the inventive concepts and methods of achieving them will be apparent from the following example embodiments that will be described in more detail with reference to the accompanying drawings. It should be noted, however, that the inventive concepts are not limited to the following example embodiments, and may be implemented in various forms. Accordingly, the example embodiments are provided only to let those skilled in the art know the category of the inventive concepts. In the drawings, embodiments of the inventive concepts are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with reference to sectional views as ideal example views of the inventive concepts. Accordingly, shapes of the example views may be modified according to manufacturing techniques and/or allowable errors. Therefore, the embodiments of the inventive concepts are not limited to the specific shape illustrated in the example views, but may include other shapes that may be created according to manufacturing processes.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Example embodiments of aspects of the present inventive concepts explained and illustrated herein include their complementary counterparts. The same reference numerals or the same reference designators denote the same elements throughout the specification.

Moreover, example embodiments are described herein with reference to cross-sectional illustrations and/or plane illustrations that are idealized example illustrations. Accordingly, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing.

Now will be described semiconductor devices and methods of fabricating the same according to embodiments of the inventive concepts.

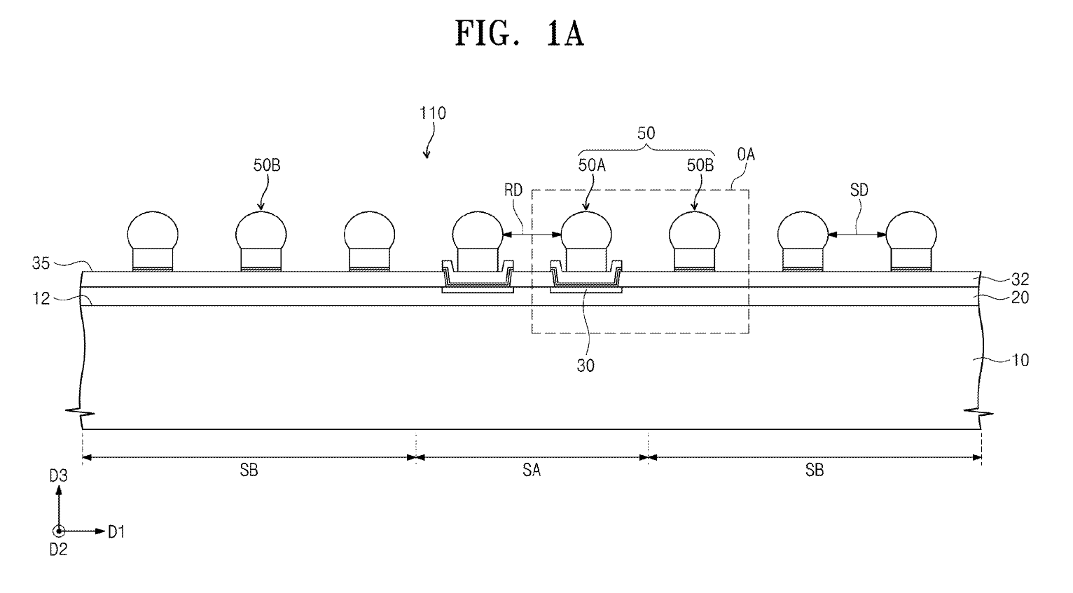

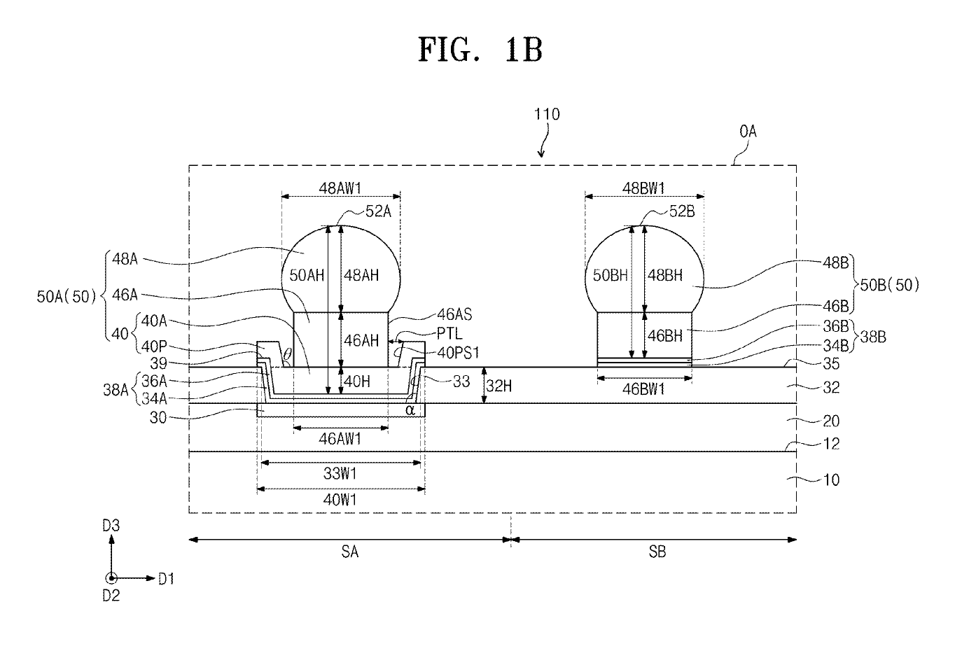

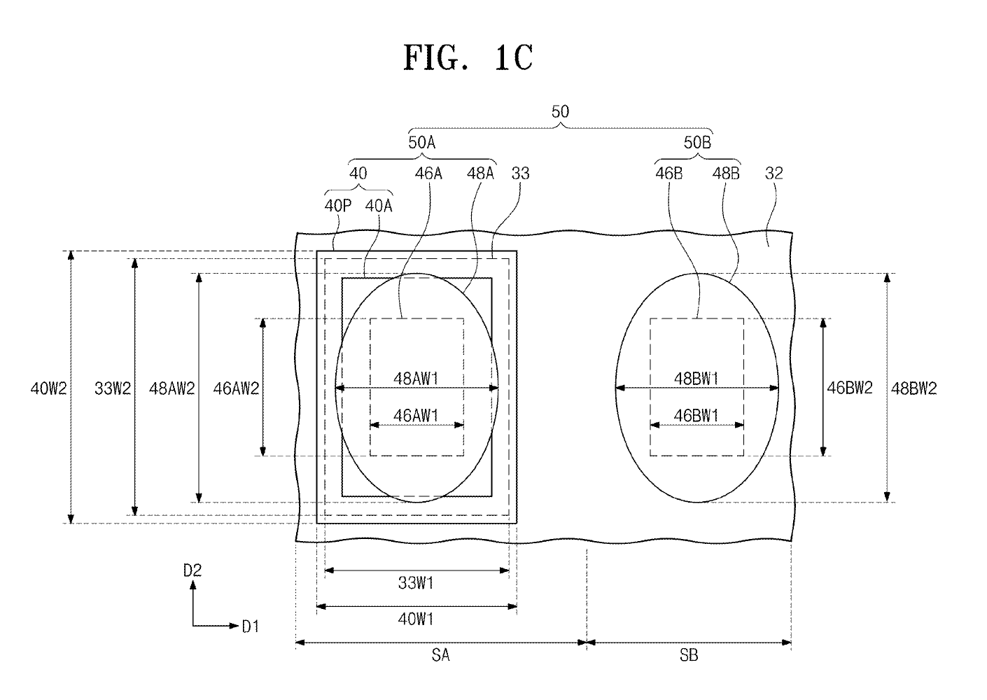

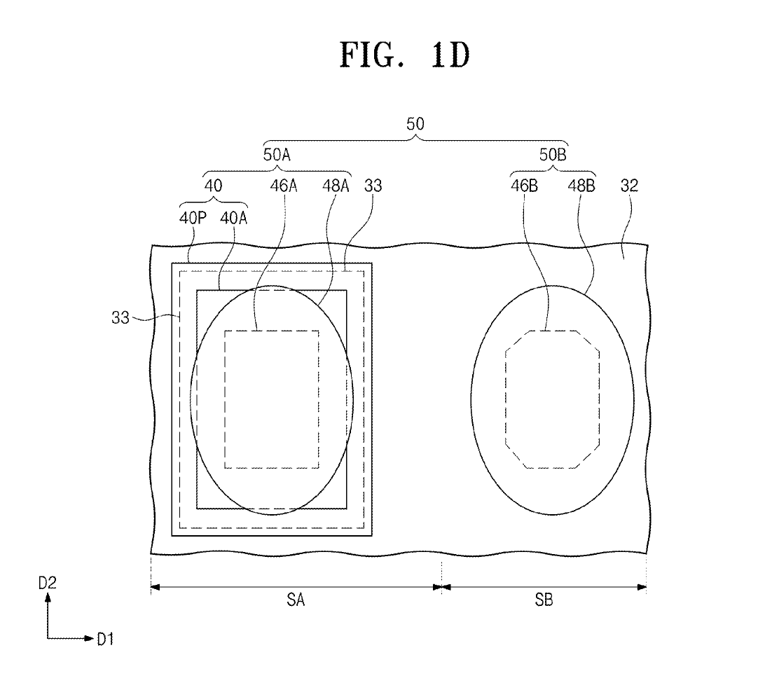

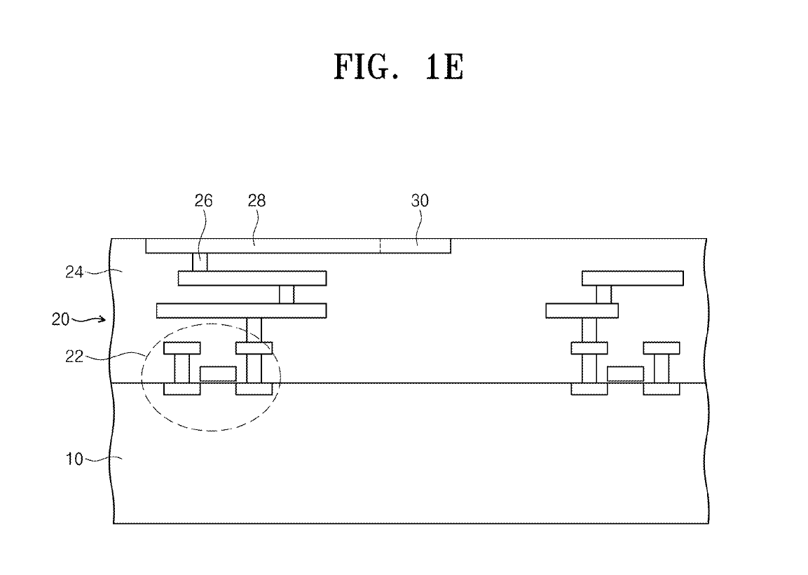

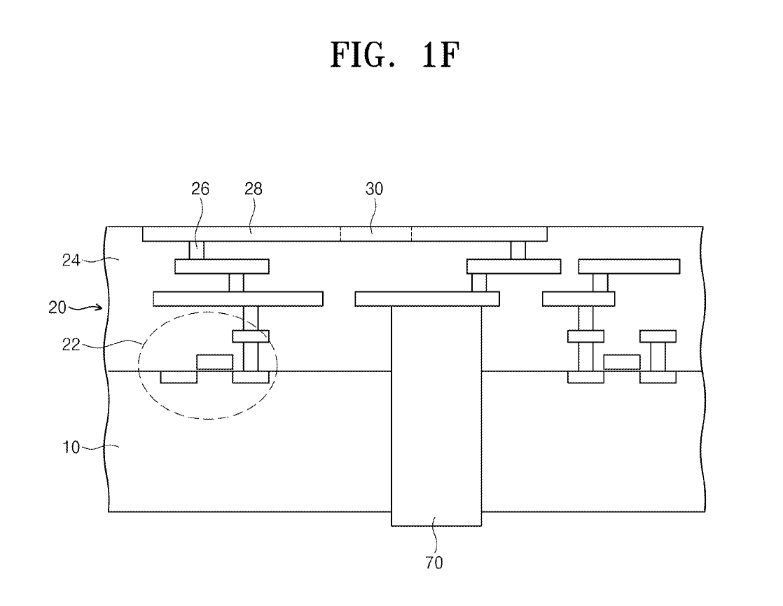

FIG. 1A is a cross-sectional view illustrating a semiconductor device according to some example embodiments of the inventive concepts. FIG. 1B is an enlarged cross-sectional view illustrating a portion of FIG. 1A. FIG. 1C and FIG. 1D are plan views illustrating a bump structure as shown in FIG. 1B, respectively. FIG. 1E and FIG. 1F are cross-sectional views illustrating a portion of an integrated circuit layer as shown in FIG. 1A, respectively.

Referring to FIGS. 1A to 1F, a semiconductor device 110 according to example embodiments of the inventive concepts may comprise a plurality of bump structures 50 on a semiconductor substrate 10. The semiconductor substrate 10 may comprise a first region SA and a second region SB. The first and second regions SA and SB may extend in a second direction D2 parallel to a main surface 12 of the semiconductor substrate 10, respectively. The first region SA may be a central region of the semiconductor substrate 10, and the second region SB may be a peripheral region of the semiconductor substrate 10. For example, the second region SB may surround the first region SA, or may include regions separated by the first region SA in a first direction D1. The first direction D1 may cross the second direction D2, and may be parallel to the main surface 12 of the semiconductor substrate 10. The semiconductor substrate 10 may be a silicon substrate, a germanium substrate, a silicon-germanium substrate, or a compound material semiconductor substrate. Alternatively, the semiconductor substrate 10 may be a semiconductor on insulator (SOI) substrate.

The semiconductor device 110 may comprise an integrated circuit layer 20, a conductive pad 30, and a passivation layer 32. As shown in FIG. 1E, the integrated circuit layer 20 may include at least one integrated circuit element 22 on and/or in the semiconductor substrate 10, wires 28 electrically connecting to the integrated circuit element 22, contact vias 26 through which adjacent wires are electrically connected, and an interlayer insulating layer 24 covering the integrated circuit element 22, the wires 28, and contact vias 26. The integrated circuit element 22 may include an active element such as a transistor, or a passive element such as a resistor, a capacitor, or an inductor. The integrated circuit element 22 may include at least one memory circuit element, at least one logic circuit element, or at least one combination thereof. The wires 28 may be constituted of multiple metal layers. Each of the wires 28 may include, for example, copper, or aluminum. Each of the contact vias 26 may include tungsten, copper, or polysilicon. The interlayer insulating layer 24 may include multiple insulating layers stacked on the semiconductor substrate 10. The interlayer insulating layer 24 may include, for example, low-k dielectric layer.

In some embodiments, as shown in FIG. 1F, the semiconductor device 110 may include at least one through-substrate via (TSV) 70 penetrating the semiconductor substrate 10. The through-silicon via 70 may penetrate a portion of the integrated circuit layer 20 and may be electrically connected to a corresponding one of the conductive pads 30 by at least one wire 28 and at least one contact via 26. The through-substrate via 70 may include metal (e.g., copper). A portion of the through-substrate via 70 may protrude from a surface of the semiconductor substrate 10.

Each of the conductive pads 30 may be electrically connected to a corresponding one of the wires 28 as shown in FIGS. 1E and 1F. The conductive pads 30 may be disposed on the first region SA of the semiconductor substrate 10. For example, a pair of the conductive pads 30 may be arranged in the first direction D1. In some embodiments, one conductive pad 30 may be disposed in the first direction D1, or more than two conductive pads 30 may be arranged in the first direction D1. In some embodiments, a plurality of the conductive pads 30 may be arranged in the second direction D2.

Each conductive pad 30 may have a circular shape, an oval shape, or a tetragonal shape, in plan view. Each conductive pad 30 may include metal. For example, each conductive pad 30 may include copper or aluminum.

Referring to FIGS. 1B and 1C, the passivation layer 32 may cover the integrated circuit layer 20 on the first and second regions SA and SB and may expose the conductive pads 30. The passivation layer 32 may have a top surface 35 that is substantially parallel to the main surface 12 of the semiconductor substrate 10. For example, the passivation layer 32 may include a first opening 33 exposing each of the conductive pads 30. The first opening 33 may have a positively sloped sidewall. An angle α between the sidewall of the first opening 33 and a top surface of the conductive pad 30 may be an obtuse angle. For example, the angle α may be about 95° to 160°. A size of the first opening 33 may be similar to a shape of the conductive pad 30, when viewed in plan view. The first opening 33 may have a first horizontal width 33W1 in the first direction D1 and a second horizontal width 33W2 in the second direction D2.

A thickness of the passivation layer 32 may be, for example, about 2 μm to 5 μm. The passivation layer 32 may include a single layer or multi-layers. The passivation layer 32 may include a polymer layer, a dielectric layer, or a combination thereof. The polymer layer may include photo-sensitive material. For example, the polymer layer may include photo sensitive polyimide (PSPI), or photo sensitive polyhydroxystyrene. The dielectric layer may include, for example, an oxide layer, a nitride layer, or a combination thereof.

The bump structures 50 may include first bump structures 50A and second bump structures 50B. The bump structures 50 may serve as external terminals of the semiconductor device 110 connecting to an outer substrate (e.g., a package substrate, an interposer, or another semiconductor device). The first bump structures 50A may be disposed on the first region SA and the second bump structures 50B may be disposed on the second region SB. For example, a pair of the first bump structures 50A may be disposed on the first region SA in the first direction D1. In some embodiments, one first bump structure 50A may be disposed in the first direction D1, or more than three bump structures 50A may be arranged in the first direction D1. The second bump structures 50B may be arranged symmetrically in the first direction D1 with respect to the first bump structures 50A. In some embodiments, a plurality of the first and second bump structures 50A and 50B may be arranged in the second direction D2, respectively.

Referring to FIG. 1A, upper portions of the first bump structures 50A may be spaced apart from each other by a first distance RD. Upper portions of the second bump structures 50B may be spaced apart from each other by a second distance SD. The first distance RD may be less than the second distance SD.

The first bump structures 50A may be active bump structures, and the second bump structures 50B may be dummy bump structures. For example, the first bump structures 50A may be electrically connected to the wires 28 (refer to FIGS. 1E and 1F) of the integrated circuit layer 20 via the conductive pads 30. Thus, input/output signals may pass through the first bump structures. The second bump structures 50B may be isolated from the conductive pads 30. Thus, the second bump structures 50B may be inactive external terminals that are not electrically connected to the wires (28 of FIGS. 1E and 1F) of the integrated circuit layer 20. For example, when the semiconductor device 110 is coupled with the package substrate or another semiconductor device, the second bump structures 50B may serve as supporters to prevent the semiconductor device 110 from inclining to one side. Additionally, the second bump structures 50B may serve as heat transfer paths to transfer heat from the semiconductor device 110 to the outside.

Referring to FIG. 1B, each of the first bump structures 50A may be disposed on a corresponding one of the conductive pads 30. Each of a first under bump metal (UBM) layers 38A may be disposed between a corresponding one of the conductive pads 30 and a corresponding one of the first bump structures 50A. Each first UBM layer 38A may include a first barrier layer 34A and a first seed layer 36A. The first seed layer 36A may be disposed on the first barrier layer 34A. The first seed layer 36A and the first barrier layer 34A may be conformally disposed in the first opening 33. The first barrier layer 34A may have a thickness, for example, ranging from about 1000Å to 3000Å. The first seed layer 36A may have a thickness, for example, ranging from about 2000Å to 5000Å. Each first UBM layer 38A may have a top surface 39 and may be extended over a top surface 35 of the passivation layer 32. The first barrier layer 34A may include, for example, Ti, Ti—W, Cr, or combinations thereof. The first seed layer 36A may include Cu, Cu alloy, Ni, Ni alloy, or combinations thereof.

Each first bump structure 50A may fill at least a portion of the first opening 33 and may extend in a third direction D3 perpendicular to the main surface 12 of the semiconductor substrate 10. Each first bump structure 50A may include a base bump layer 40, a first pillar bump layer 46A, and a first solder bump layer 48A that are sequentially stacked on a corresponding one of the conductive pads 30 (e.g., a corresponding one of the UBM layers 38). A vertical height 50AH of each first bump structure 50A may be a maximum distance ranging from a bottom surface of the base bump layer 40 to a top end of the first solder bump layer 48A. The vertical height 50AH of each first bump structure 50A may be, for example, about 26 μm to 95 μm.

The base bump layer 40 may be disposed on the first UBM layer 38A, and may be in contact with the first UBM layer 38A. That is, the base bump layer 40 may be disposed on the first seed layer 36A, and may be contact with the first seed layer 36A. The base bump layer 40 may include a base portion 40A and a protrusion portion 40P. The base portion 40A may be a region filling at least a portion of the first opening 33, and the protrusion portion 40P may be a region extending upwardly from edge region of the base portion 40A. For example, the protrusion portion 40P may be disposed adjacent to an inner sidewall of the first opening 33. The protrusion portion 40P may be extended over the top surface 35 of the passivation layer 32 away from a center of the first opening 33 or may be extended over the top surface 39 of the UBM layer 38A away from the center of the first opening 33. A thickness 40H of the base bump layer 40 may correspond to a thickness of the base portion 40A. The thickness 40H of the base bump layer 40 may be, for example, about 1 μm to 5 μm. In some embodiments, the thickness 40H of the base bump layer 40 may be identical to, or similar to the thickness 32H of the passivation layer 32. In other embodiments, the thickness 40H of the base bump layer 40 may be smaller than thickness 32H of the passivation layer 32. Therefore, a portion of the protrusion portion 40P may be lower than the top surface 35 of the passivation layer 32. For example, a portion of the protrusion portion 40P may be in the first opening 33. In yet another embodiment, the thickness 40H of the base bump layer 40 may be greater than thickness 32H of the passivation layer 32. For example, a portion of the base portion 40A may be above the first opening 33.

The base bump layer 40 may have a saucer shape. For example, the base bump layer 40 may have a circular saucer shape, an oval saucer shape, or a polygonal saucer shape such as a tetragonal saucer shape, or an octagonal saucer shape. The base bump layer 40 may have a first horizontal width 40W1 in the first direction D1 and a second horizontal width 40W2 in the second direction D2, when viewed in plan view as shown in FIG. 1C. The first horizontal width 40W1 may be less than the second horizontal width 40W2. In some embodiments, the first horizontal width 40W1 and the second horizontal width 40W2 may be substantially same. The base bump layer 40 may cover completely the conductive pad 30 exposed by the first opening 33 to protect the conductive pad 30 from being exposed to external environment. In some embodiments, an area of the base bump layer 40 is no less than an area of the conductive pad 30 when viewed in plan view so that the base bump layer 40 may cover substantially completely the conductive pad 30. As results, the base bump layer 40 may protect against corrosions of the conductive pad 30 caused by chemicals and/or moisture.

Referring to FIG. 1B, the protrusion portion 40P of the base bump layer 40 may include an inner sidewall 40PS1 opposed to a sidewall 46AS of the first pillar bump layer 46A. The inner sidewall 40PS1 of the protrusion portion 40P may slope positively in some embodiments. For example, an angle 0 between the inner sidewall 40PS1 of the protrusion portion 40P and the top surface of the base portion 40A may be an obtuse angle (e.g., 95° through 160°). The base bump layer 40 may include metal. For example, the base bump layer 40 may include, for example, Ni, Ni alloy, Cu, Cu alloy, or combinations thereof.

The first pillar bump layer 46A may be disposed on the base bump layer 40. The first pillar bump layer 46A may be spaced apart from the protrusion portion 40P of the base bump layer 40 and may be disposed on the base portion 40A of the base bump layer 40. For example, the first pillar bump layer 46A may be spaced apart from the inner sidewall 40PS1 by a distance PTL. The distance PTL may be, for example, about 1 μm to about 3 μm. A portion of the first pillar bump layer 46A may be surrounded by the protrusion portion 40P of the base bump layer 40. The first pillar bump layer 46A may have a thickness 46AH, for example, ranging from about 10 μm to 30 μm. The first pillar bump layer 46A may have a first horizontal width 46AW1 in the first direction D1 and a second horizontal width 46AW2 in the second direction D2, as shown in FIG. 1C. The first horizontal width 46AW1 may be less than the second horizontal width 46AW2. In some embodiments, the first horizontal width 46AW1 may be substantially equal to the second horizontal width 46AW2.

The first pillar bump layer 46A may have a size smaller than the base bump layer 40. That is, the first horizontal width 46AW1 of the first pillar bump layer 46A may be less than the first horizontal width 40W1 of the base bump layer 40, and the second horizontal width 46AW2 of the first pillar bump layer 46A may be less than the second horizontal width 40W2 of the base bump layer 40. The first pillar bump layer 46A may have a size smaller than the first opening 33. That is, the first horizontal width 46AW1 of the first pillar bump layer 46A may be smaller than the first horizontal width 33W1 of the first opening 33, and the second horizontal width 46AW2 of the first pillar bump layer 46A may be smaller than the second horizontal width 33W2 of the first opening 33.

The first pillar bump layer 46A may have a tetragonal shape, when viewed in plan view. In some embodiments, the first pillar bump layer 46A may have a circular shape, an oval shape, or a polygonal shape such as an octagonal shape in plan view. The first pillar bump layer 46A may include, for example, Ni, Ni alloy, Cu, Cu alloy, Au, Au alloy, or combinations thereof. In some embodiments, the first pillar bump layer 46A may include the same material with the base bump layer 40. In other embodiments, the first pillar bump layer 46A may include a material that is different from the base bump layer 40. For example, the first pillar bump layer 46A may include nickel, while the base bump layer 40 may include copper.

The first solder bump layer 48A may be disposed on the first pillar bump layer 46A. The first solder bump layer 48A may have a size greater than the first pillar bump layer 46A. The first solder bump layer 48A may have a bead shape. The first solder bump layer 48A may have a first maximum horizontal width 48AW1 in the first direction D1 and the second maximum horizontal width 48AW2 in the second direction D2 as illustrated in FIG. 1C. The first maximum horizontal width 48AW1 may be smaller than the second maximum horizontal width 48AW2. In some embodiments, the first maximum horizontal width 48AW1 may be substantially equal to the second maximum horizontal width 48AW2. The first solder bump layer 48A may have a circular shape, or an oval shape when viewed in plan view. The first solder bump layer 48A may have a vertical height 48AH of, for example, about 15 μm to 60 μm. The first solder bump layer 48A may include solder material. For example, the first solder bump layer 48A may include Sn, Pb, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, Sn—Ag—Ce, or combinations thereof.

The second bump structures 50B may be disposed on the passivation layer 32 on the second region SB of the semiconductor substrate 10. Each of the second under bump metal (UBM) layers 38B may be interposed between a corresponding one of second bump structures 50B and the passivation layer 32. Each second UBM layer 38B may include a second barrier layer 34B and the second seed layer 36B that are sequentially stacked on the passivation layer 32. The second barrier layer 34B and the first barrier layer 34A may include the same material and have the same thickness. The second seed layer 36B and the first seed layer 36A may include the same material and have the same thickness. The second barrier layer 34B and the second seed layer 36B may have the same horizontal width in the first direction D1. In some embodiments, the horizontal width of each first UBM layer 38A may be greater than that of each second UBM layer 38B. In other embodiments, the horizontal width of each first UBM layer 38A may be substantially equal to that of each second UBM layer 38B.

Each of the second bump structures 50B may include a second pillar bump layer 46B and a second solder bump layer 48B. A vertical height 50BH of each of the second bump structures 50B may be less than the vertical height 50AH of each of the first bump structures 50A. The vertical height 50BH of each of the second bump structures 50B may be a maximum distance ranging from a bottom surface of the second pillar bump layer 46B to a top end 52B of the second solder bump layer 48B. The vertical height 50BH of each of the second bump structures 50B may be, for example, about 15 μm to about 90 μm.

The second pillar bump layer 46B may be in contact with the second UBM layer 38B and may be disposed thereon. The second pillar bump layer 46B may be in contact with the second seed layer 36B. In some embodiments, the first and second pillar bump layers 46A and 46B may have the same thickness and may include the same material. The second pillar bump layer 46B may have a first horizontal width 46BW1 in the first direction D1 and a second horizontal width 46BW2 in the second direction D2, as illustrated in FIG. 1C. The first horizontal width 46BW1 may be smaller than the second horizontal width 46BW2. In some embodiments, the first horizontal 46BW1 may be substantially equal to the second horizontal width 46BW2. The second pillar bump layer 46B may have substantially the same size as the first pillar bump layer 46A. In some embodiments, the second pillar bump layer 46B may have a size different from the first pillar bump layer 46A. For example, the second pillar bump layer 46B may have a size smaller than the first pillar bump layer 46A. That is, the first horizontal width 46BW1 of the second pillar bump layer 46B may be smaller than the first horizontal width 46AW1 of the first pillar bump layer 46A, and the second horizontal width 46BW2 of the second pillar bump layer 46B may be smaller than the second horizontal width 46AW2 of the first pillar bump layer 46A. When viewed in plan view, the second pillar bump layer 46B may have a circular shape, an oval shape, or a polygonal shape such as a tetragonal shape or an octagonal shape. When viewed in plan view, shapes of the first and second pillar bump layers 46A and 46B may be substantially same. For example, shapes of the first and second pillar bump layers 46A and 46B may be substantially tetragonal shapes, as shown in FIG. 1C. In some embodiments, shapes of the first and second pillar bump layers 46A and 46B may be substantially different from each other, in plan view. For example, the shape of the first pillar bump layer 46A may have the tetragonal shape, while the shape of the second pillar bump layer 46B may have the octagonal shape, as shown in FIG. 1D.

The second solder bump layer 48B may be disposed on the second pillar bump layer 46B. The second solder bump layer 48B may have a size greater than the second pillar bump layer 46B. The second solder bump layer 48B may have a bead shape. The second solder bump layer 48B may have substantially the same vertical height and shape as the first solder bump layer 48A. In some embodiments, a maximum vertical height 48BH of the second solder bump layer 48B may be about 1.5 to 3 times greater than the thickness 46BH of the second pillar bump layer 46B. As shown in FIG. 1C, the second solder bump layer 48B may have a first maximum horizontal width 48BW1 in the first direction D1 and a second maximum horizontal width 48BW2 in the second direction D2. The first maximum horizontal width 48BW1 may be smaller than the second maximum horizontal width 48BW2. In some embodiments, the first maximum horizontal width 48BW1 may be substantially equal to the second maximum horizontal width 48BW2. In some embodiments, a size of the second solder bump layer 48B may be substantially equal to or smaller than that of the first bump layer 48A. The second solder bump layer 48B may include substantially the same solder material as the first solder bump layer 48A.

In the semiconductor devices 110 according to example embodiments of the inventive concepts, the top ends 52A of the first bump structures 50A and the top ends 52B of the second bump structures 50B may be positioned at substantially the same level. That is, a step difference between each of the top surfaces of the conductive pads 30 and the top surface of the passivation layer 32 may be supplemented by the thickness of the base bump layer 40 of each of the first bump structures 50A. Accordingly, top end of each first solder bump layer 48A and the top end of each second solder bump layer 48B may be positioned at substantially the same level.

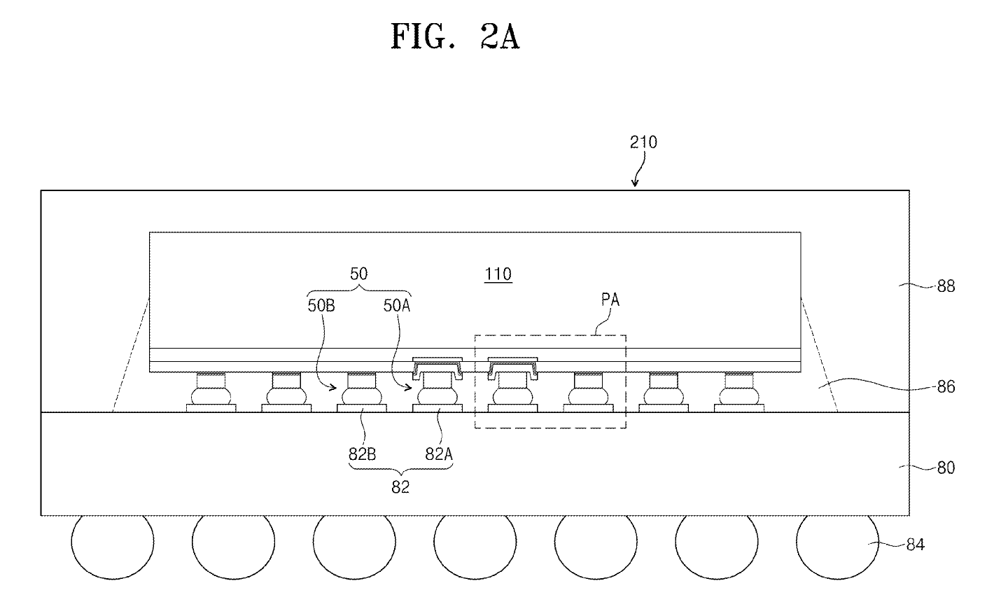

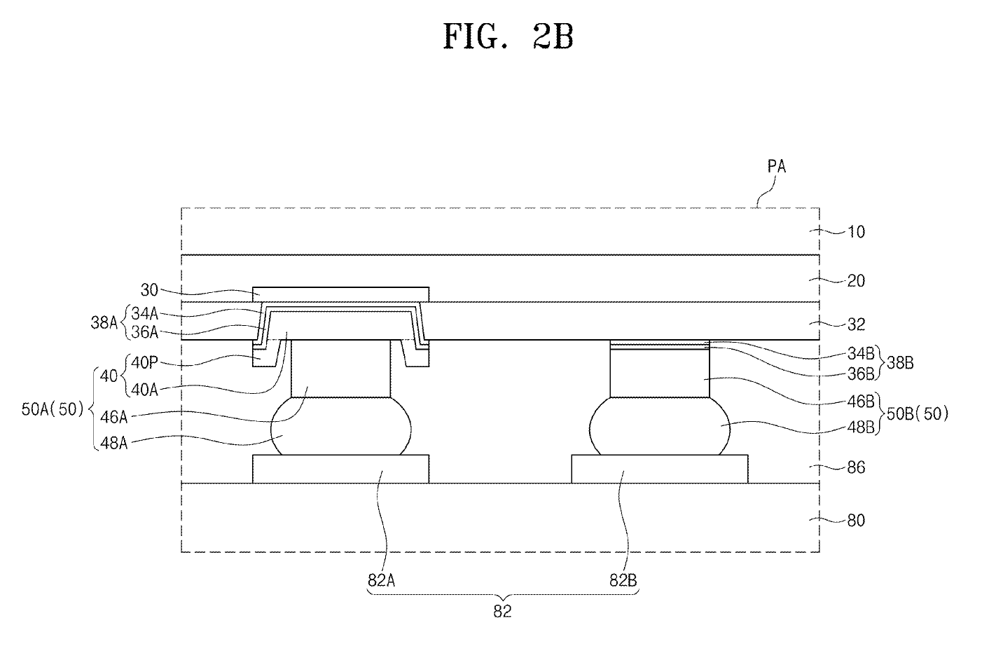

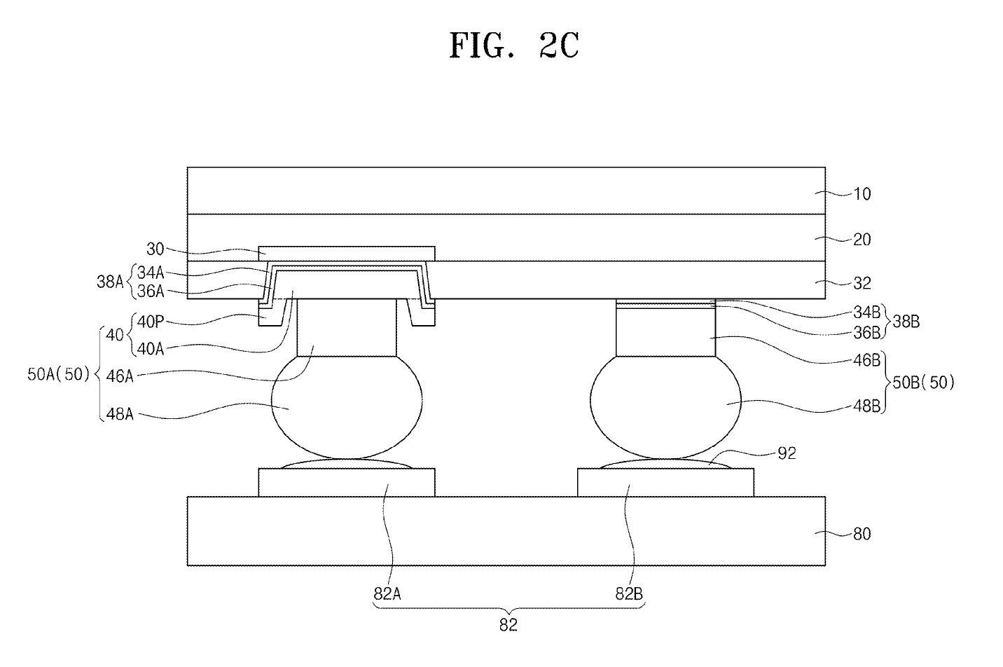

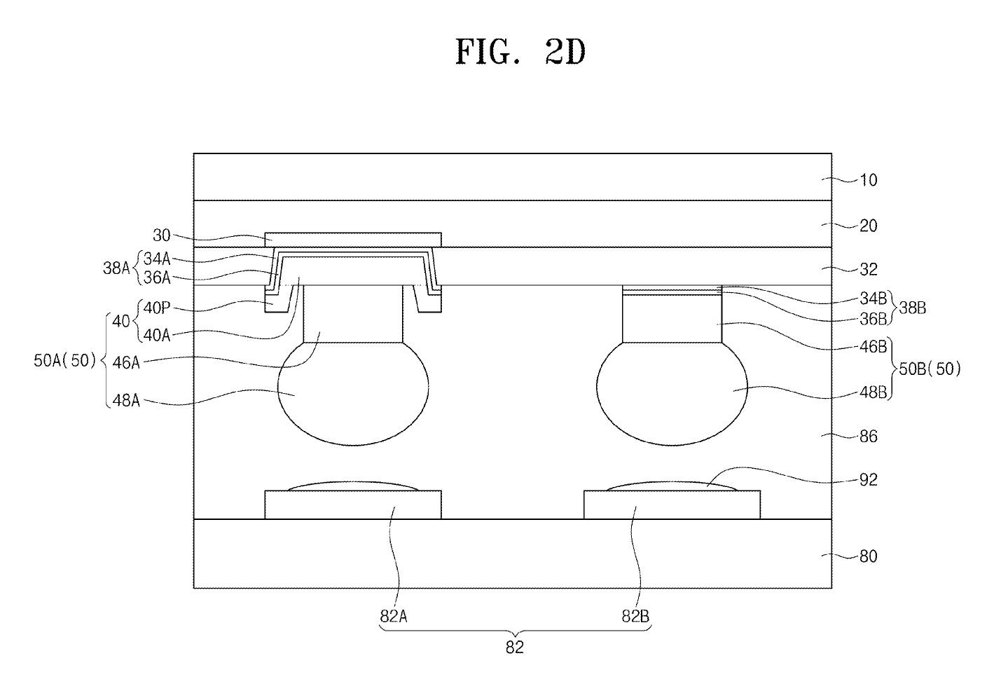

FIG. 2A is a cross-sectional view illustrating a semiconductor package including a semiconductor device according to some example embodiments of the inventive concepts, FIG. 2B is an enlarged cross-sectional view illustrating a portion PA of FIG. 2A, and FIGS. 2C and 2D are cross-sectional views illustrating methods for forming an interconnection between a bump structure of the semiconductor device and a package substrate.

Referring to FIGS. 2A to 2D, a semiconductor package 210 according to example embodiments of the inventive concepts may comprise a package substrate 80, the semiconductor device 110 including the bump structures 50 and mounted on the package substrate 80, and a mold layer 88 covering the semiconductor device 110. The package substrate 80 may comprise substrate pads 82 connected to the bump structures 50 of the semiconductor device 110 and conductive terminals 84 for electrical interconnections to the outer device. The substrate pads 82 may be disposed on a surface of the package substrate 80 and may include first substrate pads 82A and second substrate pads 82B. The first substrate pads 82A may be disposed in central region of the package substrate 80, and the second substrate pads 82B may be disposed in peripheral region of the package substrate 80. The package substrate 80 may be a printed circuit board (PCB) including wires therein. The mold layer 88 may cover the semiconductor device 110. In some embodiments, the mold layer 88 may fill a space between the semiconductor device 110 and the package substrate 80. The mold layer 88 may be, for example, epoxy molding compound (EMC). In other embodiments, an under-fill layer 86 may be formed between the semiconductor device 110 and the package substrate 80. The under-fill layer 86 may be, for example, nonconductive paste (NCP), or nonconductive film (NCF).

The semiconductor device 110 may be mounted on the package substrate 80 in a manner of flip chip bonding. As shown in FIG. 2C, the semiconductor device 110 may be mounted on the package substrate 80 in a face down state so that the bump structures 50 face the package substrate 80, thereby connecting the first and solder bump layers 48A and 48B of the first and second bump structures 50A and 50B to the first and second substrate pads 82A and 82B. Then, the first and solder bump layers 48A and 48B of the first and second bump structures 50A and 50B may be bonded to the first and second substrate pads 82A and 82B by a soldering process. Thus, the semiconductor device 110 may be electrically connected to the package substrate 80. A wetting layer 92 may be further formed on each of the substrate pads 82, so a bonding strength between the first and second solder bump layers 48A and 48B and the first and second substrate pads 82A and 82B may be enhanced. The wetting layer 92 may include, for example, Au, or Au alloy. In some embodiments, the wetting layer 92 may not be formed on the substrate pads 82.

In other embodiments, as shown in FIG. 2D, the under-fill layer 86 may be provided between the package substrate 80 and the faced-down semiconductor device 110 to cover the bump structures 50 and the substrate pads 82, and the semiconductor device 110 may be thermally pressed to bond the first and second solder bump layers 48A and 48B to the first and second substrate pads 82A and 82B. Since the top ends of the first and second bump structures 50A and 50B may be positioned at substantially the same level, the first and second bump structures 50A and 50B may be stably bonded to the first and second substrate pads 82A and 82B without defects. As a result, reliability and yields of the semiconductor package 210 may be improved.

The semiconductor device 110 may be securely mounted on the package substrate 80 using the bump structures 50 evenly disposed on the semiconductor substrate 10 and may be electrically connected to the package substrate 80. The first bump structures 50A may be electrically connected to the package substrate 80, so electrical signals may be exchanged between the semiconductor device 110 and the package substrate 80 through the first bump structures 50A. The second bump structures 50B may not be electrically connected to the package substrate 80. However, the second bump structures 50B may serve as supporters to prevent the semiconductor device 110 from leaning to one side under the flip chip bonding process. In addition, the second bump structures 50B may be utilized as heat transfer paths such that the heat generated from the semiconductor device 110 can be transferred to the package substrate 80 through the second bump structures 50B. Thus, the semiconductor package 210 may have improved thermal and/or mechanical durability. In some embodiments, the semiconductor package 210 may include a plurality of the semiconductor devices 110 mounted on the package substrate 80 in the manner of the flip chip bonding such that high packing density can be accomplished. In some embodiments, the bump structures 50 of the semiconductor device 110 may be connected to an interposer, or another semiconductor device.

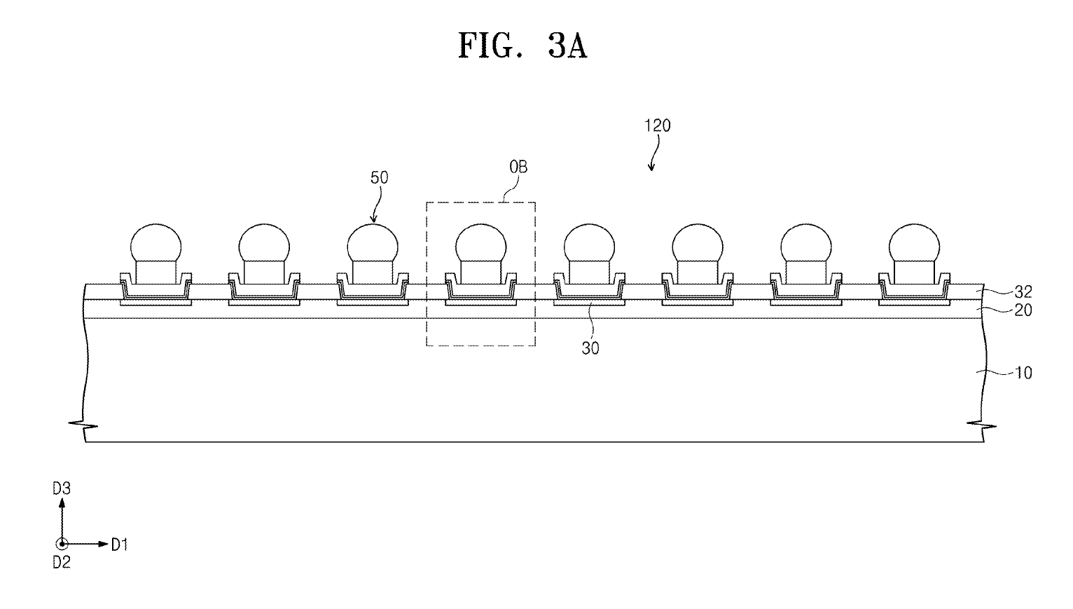

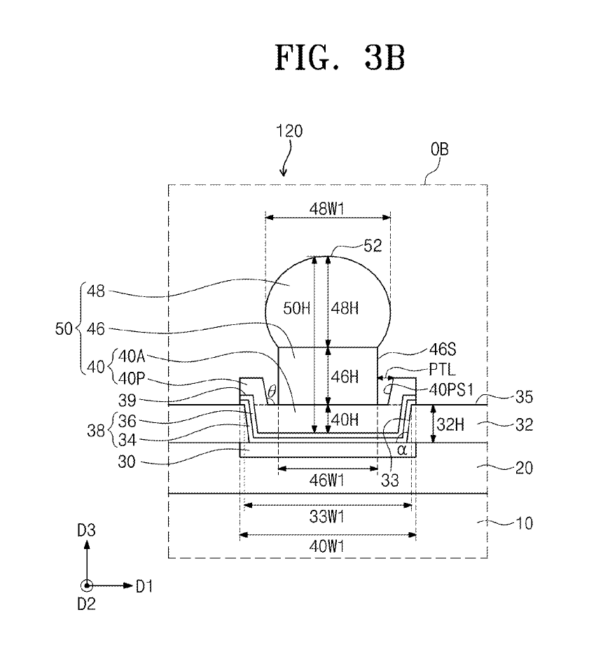

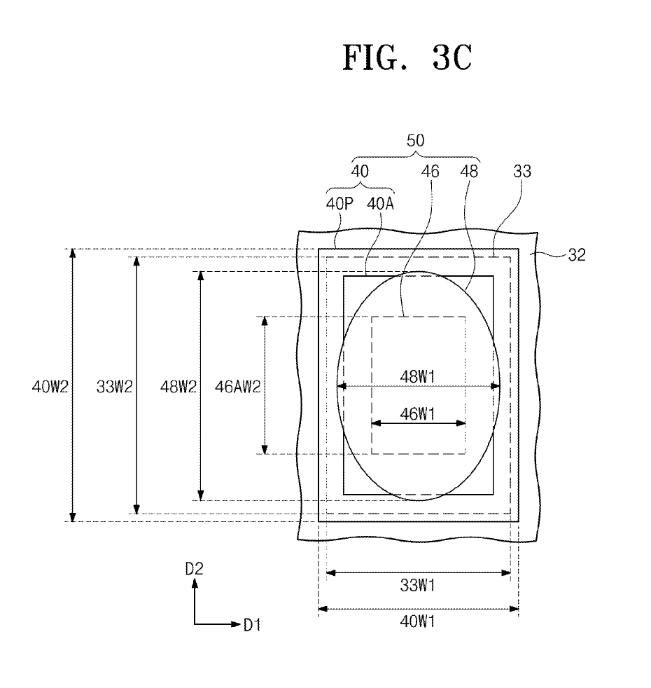

FIG. 3A is a cross-sectional view illustrating a semiconductor device according to some example embodiments of the inventive concepts, FIG. 3B is an enlarged cross-sectional view illustrating a portion OB of FIG. 3A, and FIG. 3C is a plan view illustrating bump structures as shown in FIG. 3B.

Hereinafter, the descriptions to the same elements as described in the embodiments illustrated in FIGS. 1A to 1F will be omitted or mentioned briefly for the purpose of ease and convenience in explanation

Referring to FIGS. 3A to 3C, a semiconductor device 120 according to example embodiments of the inventive concepts may comprise an integrated circuit layer 20, conducive pads 30, a passivation layer 32, and bump structures 50. In some embodiments, as shown in FIG. 1F, the semiconductor device 120 may include at least one through-substrate via 70. The through-substrate via 70 may be electrically connected to a corresponding one of the conductive pads 30.

The conductive pads 30 may be electrically connected to the wires 28 illustrated in FIGS. 1E and 1F. The conductive pads 30 may be, for example, arranged in a matrix manner. In some embodiments, the conductive pads 30 may be disposed on an edge region and/or a central region of the semiconductor substrate 10.

When viewed in plan view, each conductive pad 30 may have a circular shape, an oval shape, or a tetragonal shape. Each conductive pad 30 may include metal. For example, each conductive pad 30 may include Al, or Cu.

The passivation layer 32 may cover the integrated circuit layer 20 and may expose the conductive pads 30. For example, the passivation layer 32 may include a first opening 33 exposing each of the conductive pads. The first opening 33 may have a positively sloped sidewall. The first opening 33 may have a first horizontal width 33W1 in the first direction D1 and a second horizontal width 33W2 in the second direction D2.

Each of the bump structures 50 may be disposed on a corresponding one of the conductive pads 30. The bump structures 50 may be electrically connected to the wires 28 (refer to FIGS. 1E and 1F) of the integrated circuit layer 20 via the conductive pads 30. Therefore, input/output signals may pass through the bump structures 50. The bmp structures 50 may serve as a heat transfer paths.

Each under bump metal (UBM) layer 38 may be disposed between a corresponding one of the conductive pads 30 and a corresponding one of the bump structures 50. Each UBM layer 38 may include a barrier layer 34 and a seed layer 36 that are sequentially stacked on a corresponding one of the conductive pads 30. Each UBM layer 38 may be conformally disposed in the first opening 33. Each UBM layer 38 may be extended over the top surface 35 of the passivation layer 32.

Each bump structure 50 may fill at least a portion of the first opening 33 and may extend in a third direction D3. Each bump structure 50 may include a base bump layer 40, a pillar bump layer 46, and a solder bump layer 48 that are sequentially stacked on a corresponding one of the conductive pads 30 (e.g., a corresponding one of the UBM layers). A vertical height 50H of each bump structure 50 may be a maximum distance ranging from a bottom surface of the base bump layer 40 to a top end of the solder bump layer 48 (i.e., a top end 52 of the bump structure 50). The vertical height 50H of each bump structure 50 may be, for example, about 26 μm to 95 μm.

The base bump layer 40 may be disposed on the UBM layer 38 and may be in contact with the UBM layer 38. The base bump layer 40 may include a base portion 40A and a protrusion portion 40P. The base portion 40A may be a region filling at least a portion of the first opening 33, and the protrusion portion 40P may be a region extending upwardly from edge region of the base portion 40A. For example, the protrusion portion 40P may be disposed adjacent to an inner sidewall of the first opening 33. The protrusion portion 40P may be extended over the top surface 35 of the passivation layer 32 away from a center of the first opening 33 or may be extended over the top surface 39 of the UBM layer 38 away from the center of the first opening 33. A thickness 40H of the base bump layer 40 may correspond to a thickness of the base portion 40A. The thickness 40H of the base bump layer 40 may be, for example, about 1 μm to 5 μm. In some embodiments, the thickness 40H of the base bump layer 40 may be identical to, or similar to the thickness 32H of the passivation layer 32. In other embodiments, the thickness 40H of the base bump layer 40 may be less than thickness 32H of the passivation layer 32. Therefore, a portion of the protrusion portion 40P may be lower than the top surface 35 of the passivation layer 32. For example, a portion of the protrusion portion 40P may be in the first opening 33. In yet another embodiment, the thickness 40H of the base bump layer 40 may be greater than thickness 32H of the passivation layer 32. For example, a portion of the base portion 40A may be above the first opening 33.

The base bump layer 40 may have a saucer shape. For example, the base bump layer 40 may have a circular saucer shape, an oval saucer shape, or a polygonal saucer shape such as a tetragonal saucer shape, or an octagonal saucer shape. The base bump layer 40 may have a first horizontal width 40W1 in the first direction D1 and a second horizontal width 40W2 in the second direction D2, when viewed in plan view as shown in FIG. 3C. The first horizontal width 40W1 may be less than the second horizontal width 40W2. In some embodiments, the first horizontal width 40W1 and the second horizontal width 40W2 may be substantially same. The base bump layer 40 may cover completely the conductive pad 30 exposed by the first opening 33 to protect the conductive pad 30 from being exposed to external environment. In some embodiments, an area of the base bump layer is no less than an area of the conductive pad when viewed in plan view so that the base bump layer 40 may cover completely the conductive pad 30. As a result, the base bump layer 40 may protect against corrosions of the conductive pad 30 caused by chemicals and/or moisture.

The protrusion portion 40P of the base bump layer 40 may include an inner sidewall 40PS1 opposed to a sidewall 46S of the pillar bump layer 46. The inner sidewall 40PS1 of the protrusion portion 40P may be positively sloped. In some embodiments, an angle 0 between the inner sidewall 40PS1 of the protrusion portion 40P and the top surface of the base portion 40A may be an obtuse angle (e.g., 95° through 160°), for example. The base bump layer 40 may include metal. For example, the base bump layer 40 may include Ni, Ni alloy, Cu, Cu alloy, Au, Au alloy, or combinations thereof.

The pillar bump layer 46 may be disposed on the base bump layer 40. The pillar bump layer 46 may be spaced apart from the protrusion portion 40P of the base bump layer 40 and may be disposed on the base portion 40A of the base bump layer 40. For example, the pillar bump layer 46 may be spaced apart from the inner sidewall 40PS1 by a distance PTL. The distance PTL may be, for example, about 1 μm to 3 μm. A portion of the pillar bump layer 46 may be surrounded by the protrusion portion 40P of the base bump layer 40. The pillar bump layer 46 may have a thickness 46H, for example, ranging from about 10μm to 30μm. The pillar bump layer 46 may have a first horizontal width 46W1 in the first direction D1 and a second horizontal width 46W2 in the second direction D2, as shown in FIG. 3C. The first horizontal width 46W1 may be less than the second horizontal width 46W2. In some embodiments, the first horizontal width 46W1 may be substantially equal to the second horizontal width 46W2.

The pillar bump layer 46 may have a size smaller than the base bump layer 40. That is, the first horizontal width 46W1 of the pillar bump layer 46 may be smaller than the first horizontal width 40W1 of the base bump layer 40, and the second horizontal width 46W2 of the pillar bump layer 46 may be smaller than the second horizontal width 40W2 of the base bump layer 40. The pillar bump layer 46 may have a size smaller than the first opening 33. That is, the first horizontal width 46W1 of the pillar bump layer 46 may be smaller than the first horizontal width 33W1 of the first opening 33, and the second horizontal width 46W2 of the pillar bump layer 46 may be smaller than the second horizontal width 33W2 of the first opening 33.

When viewed in plan view, the pillar bump layer 46 may have a tetragonal shape. In some embodiments, the pillar bump layer 46 may have a circular shape, oval shape, or a polygonal shape such as an octagonal shape, in plan view. The pillar bump layer 46 may include Ni, Ni alloy, Cu, Cu alloy, Au, Au alloy, or combinations thereof. The pillar bump layer 46 may include the same material with the base bump layer 40. In some embodiments, the pillar bump layer 46 may include a material that is different from the base bump layer 40. For example, the pillar bump layer 46 may include nickel, while the base bump layer 40 may include copper.

The solder bump layer 48 may be disposed on the pillar bump layer 46. The solder bump layer 48 may have a size greater than the pillar bump layer 46. The solder bump layer 48 may have a bead shape. As shown in FIG. 3C, the solder bump layer 48 may have a first maximum horizontal width 48W1 in the first direction D1 and the second maximum horizontal width 48W2 in the second direction D2. The first maximum horizontal width 48W1 may be smaller than the second maximum horizontal width 48W2. In some embodiments, the first maximum horizontal width 48W1 may be substantially equal to the second maximum horizontal width 48W2. The solder bump layer 48 may have a circular shape, or an oval shape, when viewed in plan view. The solder bump layer 48 may have a vertical height 48H of, for example, about 15 μm to 60μm. In some embodiments, a maximum vertical height 48H of the solder bump layer 48 may be about 1.5 to 3 times greater than the thickness 46H of the pillar bump layer 46. The solder bump layer 48 may include solder material. For example, the solder bump layer 48 may include Sn, Pb, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, Sn—Ag—Ce, or combinations thereof.

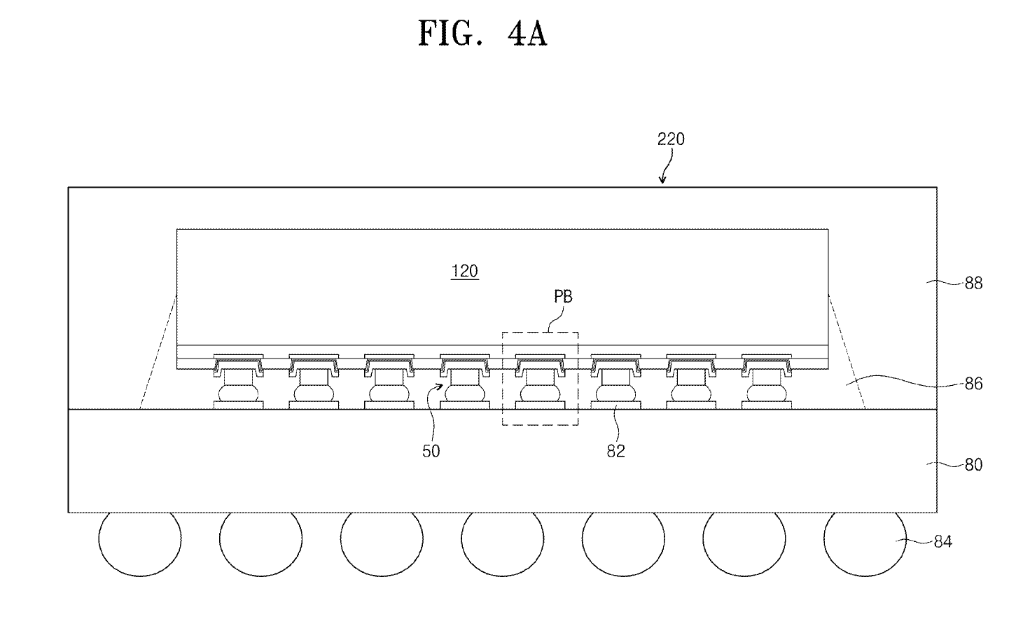

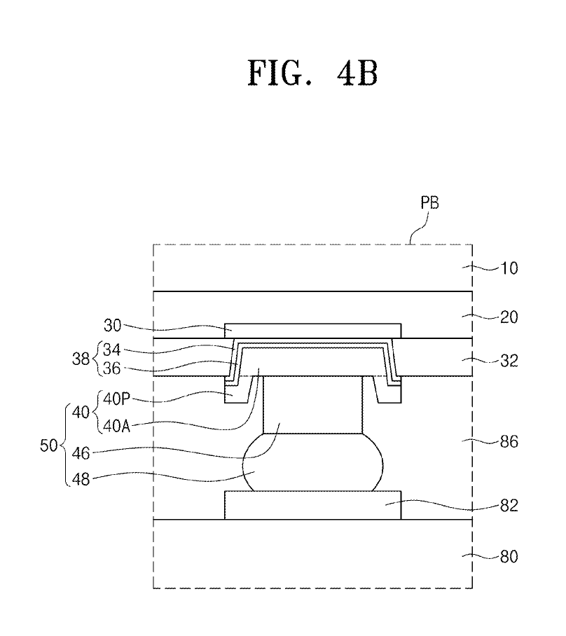

FIG. 4A is a cross-sectional view illustrating a semiconductor package including a semiconductor device according to some example embodiments of the inventive concepts, and FIG. 4B is an enlarged cross-sectional view illustrating a portion PB of FIG. 4A.

Hereinafter, the descriptions to the same elements as described in the embodiments illustrated in FIGS. 2A to 2D will be omitted or mentioned briefly for the purpose of ease and convenience in explanation

Referring to FIGS. 4A and 4B, a semiconductor package 220 according to example embodiments of the inventive concepts may comprise a package substrate 80, the semiconductor device 120 including the bump structures 50 and mounted on the package substrate 80, and a mold layer 88 covering the semiconductor device 120. The package substrate 80 may comprise substrate pads 82 connected to the bump structures 50 of the semiconductor device 120 and conductive terminals 84 for electrical interconnections to the outer device. The substrate pads 82 may be disposed on the package substrate 80. In some embodiments, an under-fill layer 86 may be formed between the semiconductor device 120 and the package substrate 80.

The semiconductor device 120 may be mounded on the package substrate 80 in a manner of flip chip bonding. For example, the bump structures 50 of the semiconductor device 120 may be bonded to the substrate pads 82 of the package substrate 80 in the same methods as described with reference to FIGS. 2C and 2D. In other words, each of the solder bump layers 48 of the bump structures 50 may be bonded to a corresponding one of the substrate pads 82. Thus, the semiconductor device 120 may be securely mounted on the package substrate 80 and may be electrically connected to the package substrate 80. Electrical signals may be exchanged between the semiconductor device 120 and the package substrate 80 through the bump structures 50, and heat generated from the semiconductor device 50 may be emitted or transferred through the bump structures 50. In some embodiments, the semiconductor package 220 may include a plurality of the semiconductor devices 120 mounted on the package substrate 80 in the manner of the flip chip bonding such that high-packing density can be accomplished. In some embodiments, the bump structures 50 of the semiconductor device 120 may be connected to an interposer, or another semiconductor device.

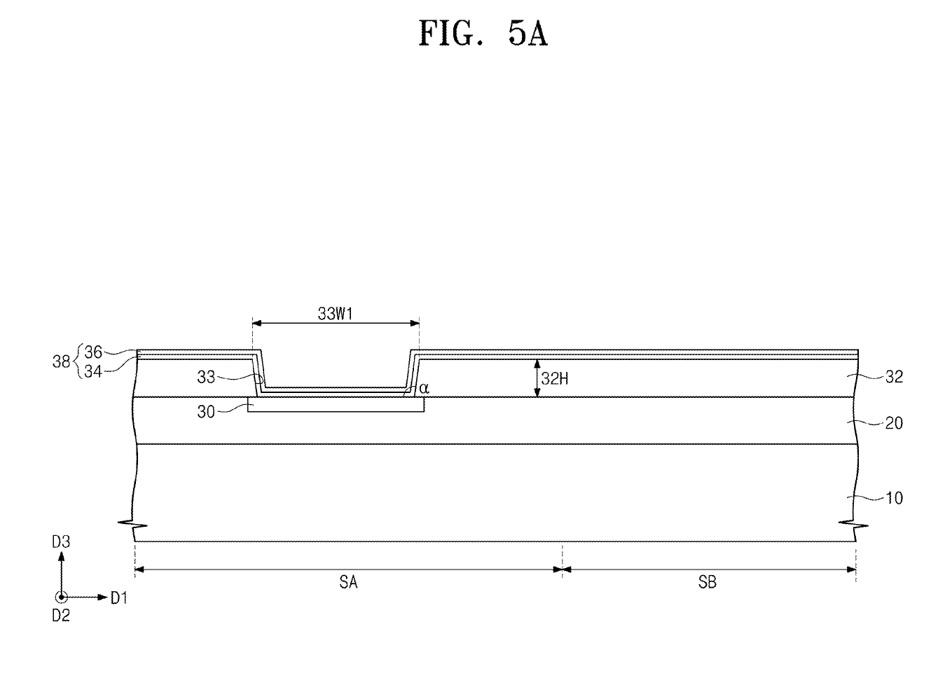

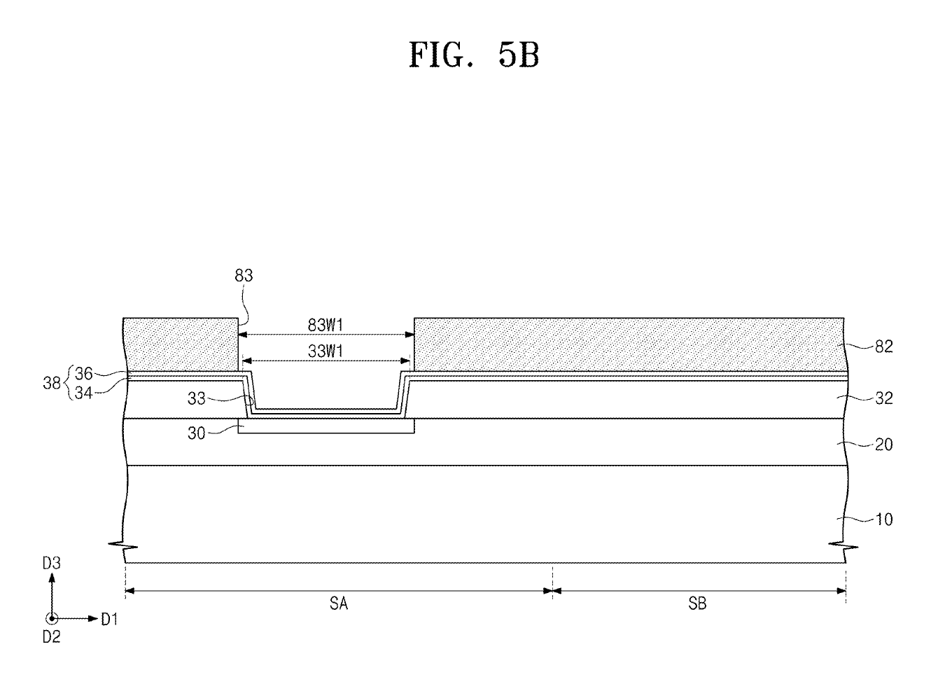

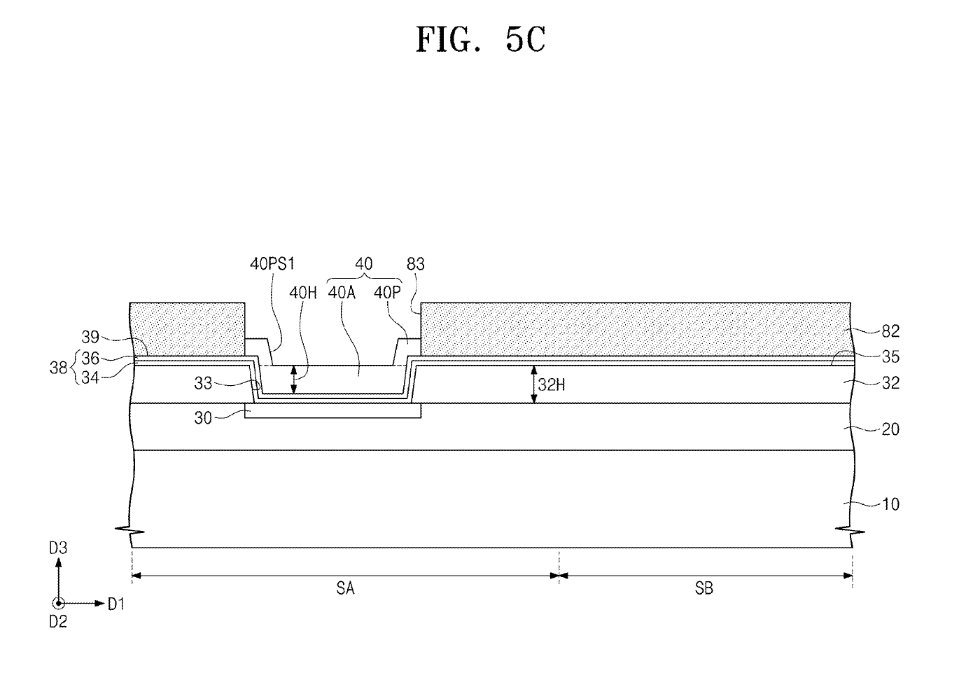

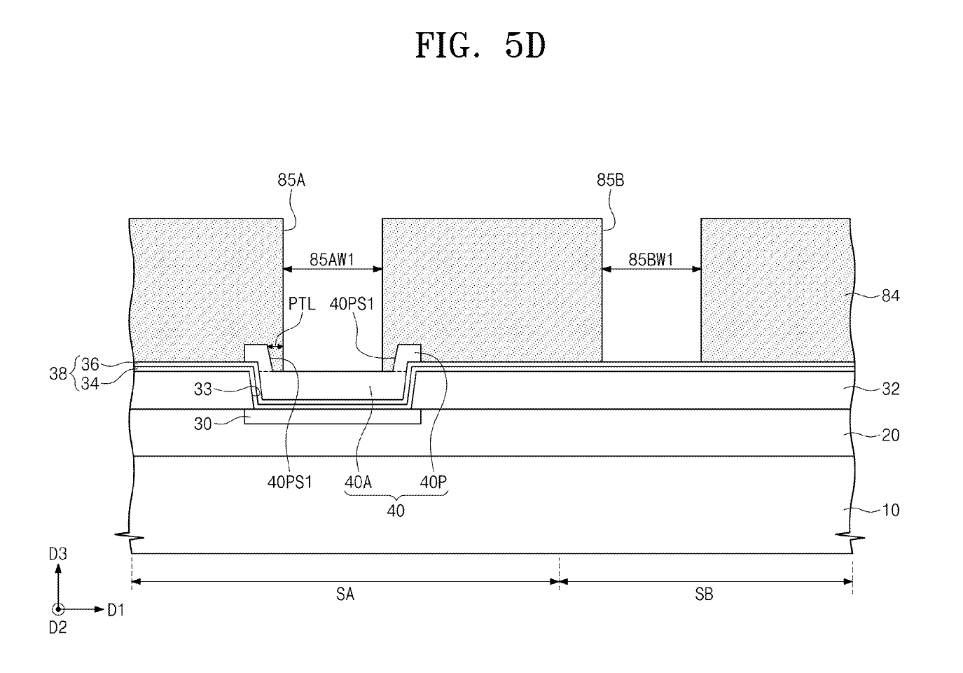

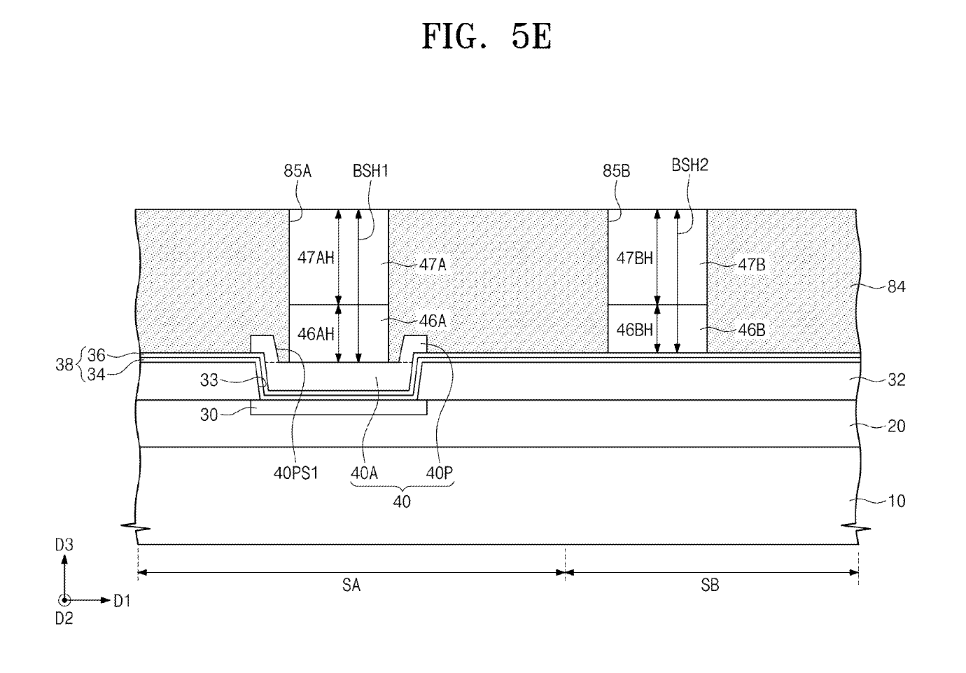

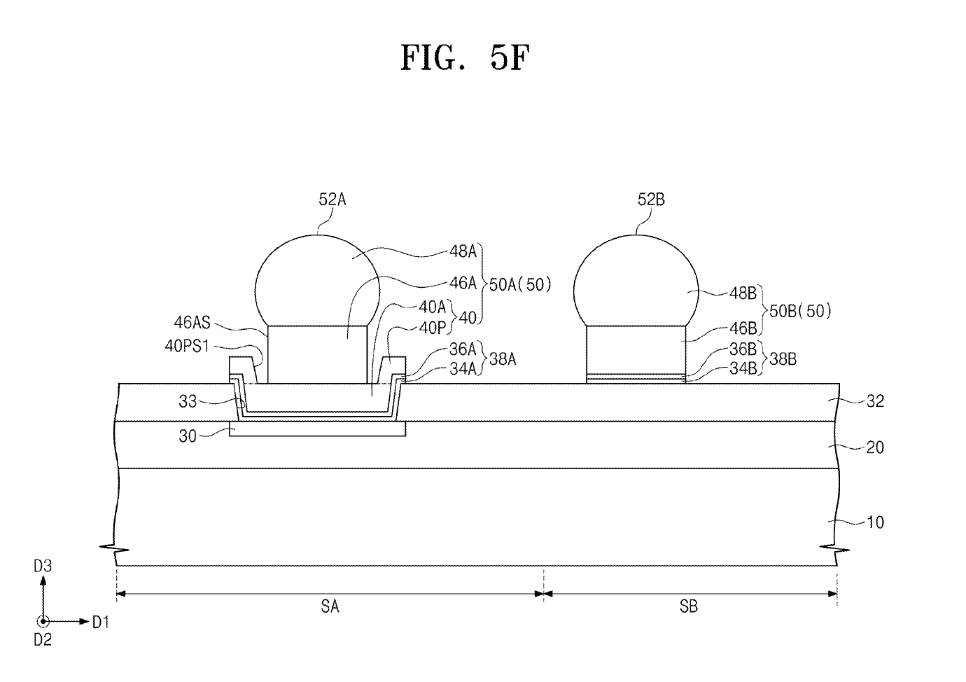

FIGS. 5A to 5F are cross-sectional views illustrating a method for fabricating a semiconductor device according to some example embodiments of the inventive concepts.

Referring to FIG. 5A, an under bump metal (UBM) layer 38 may be formed on the semiconductor substrate 10 that a conductive pad 30 and a passivation layer 32 are provided thereon. The semiconductor substrate 10 may include a first region SA and a second region SB. For example, the first region SA may be a central region of the semiconductor substrate 10, and the second region SB may be a peripheral region of the semiconductor substrate 10. The second region SB may surround the first region SA, or may include regions separated by the first region SA in the first direction D1. The semiconductor substrate 10 may be a silicon substrate, a germanium substrate, a silicon-germanium substrate, or a compound material semiconductor substrate. In some embodiments, the semiconductor substrate 10 may be a semiconductor on insulator (SOI) substrate.

An integrated circuit layer 20 may be formed underneath the passivation layer 32. The integrated circuit layer 20 may include at least one integrated circuit element 22 on and/or in the semiconductor substrate 10, wires 28 connected to the integrated circuit elements 22, connecting vias 26 connecting the wires 28, and an interlayer insulating layer 24 covering the integrated circuit elements 22, the wires 28, and the contact vias 26, as shown in FIG. 1E. The integrated circuit element 22 may include a memory circuit element, logic circuit element or a combination thereof. In some embodiments, as shown in FIG. 1F, the semiconductor device 110 may include at least one through-substrate via 70 penetrating the semiconductor substrate 10. The through-substrate via 70 may penetrate a portion of the integrated circuit layer 20 and may be electrically connected to a corresponding one of the conductive pads 30 by at least one wire 28 and at least one contact via 26.

The conductive pad 30 may be formed on the semiconductor substrate 10 to be electrically connected to a corresponding one of the wires 28 as shown in FIGS. 1E and 1F. The conductive pad 30 may be formed on the first region SA of the semiconductor substrate 10. The conductive pad 30 may have a circular shape, an oval shape, or a tetragonal shape, when viewed in plan view. The conductive pad 30 may include metal. For example, the conductive pad 30 may include copper or aluminum.

The passivation layer 32 may be formed on the first and second regions SA and SB of the semiconductor substrate 10. The passivation layer 32 may cover the integrated circuit layer 20 on the first and second regions SA and SB and may expose the conductive pad 30. For example, the passivation layer 32 may include a first opening 33 exposing the conductive pad 30. The first opening 33 may be formed by etching the passivation layer 32. The first opening 33 may have a positively sloped inner sidewall. An angle α between the inner sidewall of the first opening 33 and a top surface of the conductive pad 30 may be an obtuse angle. For example, the angle α may be 95° to 160°. The first opening 33 may have a first horizontal width 33W1 in the first direction D1. The first opening 33 may be similar in shape to the conductive pad 30, when viewed in plan view.

The passivation layer 32 may include a single layer or multi-layers. A thickness 32H of the passivation layer 32 may be, for example, about 3 μm to 5 μm. The passivation layer 32 may include a polymer layer or a dielectric layer, or a combination thereof. The polymer layer may include photo-sensitive material. For example, the polymer layer may include photo sensitive polyimide (PSPI), or photo sensitive polyhydroxystyrene. The dielectric layer may include, for example, an oxide layer, a nitride layer, or a combination thereof.

The UBM layer 38 may be formed on the passivation layer 32 including the first opening 33. The UBM layer 38 may be conformally formed in the first opening 33 and on the passivation layer 32. The UBM layer 38 may include a barrier layer 34 and a seed layer 36 that are sequentially stacked on the conductive pad 30 and the passivation layer 32. The bather layer 34 may have a thickness, for example, ranging from about 1000Å to 3000Å. The seed layer 36 may have a thickness, for example, ranging from about 2000Å to 5000Å. The barrier layer 34 may include, for example, Ti, Ti—W, Cr, or combinations thereof. The seed layer 36 may include Cu, Cu alloy, Ni, Ni alloy, or combinations thereof.

Referring to FIG. 5B, a first mask pattern 82 including a second opening 83, that has a size greater than the first opening 33 and overlap with the first opening 33, may be formed on the UBM layer 38. A horizontal width 83W1 of the second opening 83 may be greater than the first horizontal width 33W1 of the first opening 33. Thus, a portion of the seed layer 36 disposed in the first opening 33 and on the passivation layer 32 adjacent to the first opening 33 may be exposed by the second opening 83. The first mask pattern 82 may be formed by, for example, coating and patterning processes of a photoresist layer. The first mask pattern 82 may have a thickness, for example, ranging from about 3 μm to 10 μm.

Referring to FIG. 5C, a base bump layer 40 may be formed on the UBM layer 38. For example, the base bump layer 40 may be formed on the seed layer 36 using plating (e.g., electro plating, or electroless plating) process. The base bump layer 40 may fill at least a portion of the first opening 33 and extend upwardly along the inner sidewall of the second opening 83. Accordingly, the base bump layer 40 may include a base portion 40A that is in contact with the UBM layer 38 and fills at least a portion of the first opening 33, and a protrusion portion 40P that protrudes upwardly in the third direction D3 from an edge region of the base portion 40A. For example, the protrusion portion 40P may be disposed adjacent to the inner sidewall of the first opening 33. The protrusion portion 40P may be extended over a top surface 35 of the passivation layer 32 away from a center of the first opening 33 or may be extended over a top surface 39 of the UBM layer 38 away from the center of the first opening 33. The protrusion portion 40P may include a sloped inner sidewall PS1. The inner sidewall PS1 of the protrusion portion 40P may be positively sloped in some embodiments. The base bump layer 40 may have a thickness 40H, for example, ranging from about 1 μm to 5 μm. The thickness 40H of the base bump layer 40 may correspond to a thickness of the base portion 40P of the base bump layer 40. In some embodiments, thickness 40H of the base bump layer 40 may be substantially identical to the thickness 32H of the passivation layer 32. In other embodiments, thickness 40H of the base bump layer 40 may be substantially less than the thickness 32H of the passivation layer 32. The base bump layer 40 may have a saucer shape. For example, the base bump layer 40 may have a circular saucer shape, an oval saucer shape, or a polygonal saucer shape such as a tetragonal saucer shape or an octagonal saucer shape. The base bump layer 40 may include metal (e.g., Cu, Cu alloy, Ni, Ni alloy, Au, Au alloy, or combinations thereof). The base bump layer 40 may cover fully the conductive pad 30 such that the conductive pad 30 is not exposed to outer environment.

Referring to FIG. 5D, the first mask pattern 82 may be removed, then the second mask pattern 84, that exposes a portion of the base bump layer 40 on the first region SA of the semiconductor substrate 10 and a portion of the UBM layer 38 on the second region SB of the semiconductor substrate 10, may be formed on the semiconductor substrate 10. The first mask pattern 82 may be removed using an ashing process. The second mask pattern 84 may include a third opening 85A exposing a portion of the base bump layer 40 on the first region SA and a fourth opening 85B exposing a portion of the UBM layer (e.g., a portion of the seed layer 36) on the passivation layer 32 on the second region SB. The second mask pattern 84 may be formed in such a way that an inner sidewall of the third opening 85A is spaced apart from the inner sidewall 40PS1 of the protrusion portion 40P of the base bump layer 40 by a maximum distance PTL. The maximum distance PTL may be, for example, about 1 μm to 3 μm. The second mask pattern 84 may be formed to cover the protrusion portion 40P of the base bump layer 40. A horizontal width 85AW1 of the third opening 85A in the first direction D1 may be greater than a horizontal width 85BW1 of the fourth opening 85B in the first direction D1. In some embodiments, the horizontal width 85AW1 of the third opening 85A may be substantially equal to the horizontal width 85BW1 of the fourth opening 85B. The second mask pattern 84 may be formed by, for example, coating and patterning processes of a photoresist layer. When viewed in plan view, the third and fourth openings 85A and 85B may have a polygonal shape such a tetragonal shape or an octagonal shape. In some embodiments, the third and fourth openings 85A and 85B may have a circular shape or an oval shape, in plan view. The third and fourth openings 85A and 85B may be same or different in shape.

Referring to 5E, a first pillar bump layer 46A and a first solder layer 47A may be formed in the third opening 85A, and a second pillar bump layer 46B and a second solder layer 47B may be formed in the fourth opening 85B. For example, on the first region SA, the first pillar bump layer 46A may be formed on the base bump layer 40, and on the second region SB, a second pillar bump layer 46B may be formed on the seed layer 36 on the passivation layer 32. The first pillar bump layer 46A may be formed on the base portion 40A of the base bump layer 40 and may be spaced apart from the protrusion portion 40P of the base bump layer 40. Thus, a horizontal width of the first pillar bump layer 46A in the first direction D1 may be less than that of the base bump layer 40 in the first direction D1. The horizontal width of the first pillar bump layer 46A in the first direction D1 may be less than the horizontal width 33W1 (refer to of FIG. 5A) of the first opening layer 33 in the first direction D1. The first and second pillar bump layers 46A and 46B may be formed using the same plating (e.g., electro plating, electroless plating) process. The first pillar bump layers 46A may be filled a portion of the third opening 85A, and second pillar bump layers 46B may be filled a portion of the fourth opening 85B. Each of the first and second pillar bump layers 46A and 46B may include metal (e.g., Cu, Cu alloy, Ni, Ni alloy, Au, Au alloy, or combinations thereof). The first and second pillar bump layers 46A and 46B and the base bump layer 40 may be formed of a same material, or a different material. For example, the base bump layer 40 may be formed of copper, and the first and second pillar bump layers 46A and 46B may be formed of copper or nickel. In some embodiments, a thickness 46AH of the first pillar bump layer 46A may be substantially equal to a thickness 46BH of the second pillar bump layer 46B. The thicknesses 46AH and 46BH of the first and second pillar bump layers 46A and 46B may be, for example, about 10 μm to 30 μm.

The first solder layer 47A may be formed on the first pillar bump layer 46A, and the second solder layer 47B may be formed on the second pillar bump layer 46B. The first solder layer 47A may fill the third opening 85A, and the second solder layer 47B may fill the fourth opening 85B. In some embodiments, thickness 47AH and 47BH of the first and second solder layer 47A and 47B may be substantially same. For example, each of the thicknesses 47AH and 47BH of the first and second solder layer 47A and 47B may be, for example, about 15 μm to 60 μm. The first and second solder layers 47A and 47B may be formed by the same plating (e.g., electro plating, or electroless plating) process at the same time. Each of the first and second solder layers 47A and 47B may include solder material. For example, the solder layer 47 may include Sn, Pb, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, Sn—Ag—Ce, or combinations thereof.

A top surface of the first solder layer 47A and a top surface of the second solder layer 47B may be coplanar. That is, a first vertical height BSH1 ranging from a bottom surface of the first pillar bump layer 46A to the top surface of the first solder layer 47A may be substantially the same as a second vertical height BSH2 ranging from a bottom surface of the second pillar bump layer 46B to the top surface of the second solder layer 47B.

Referring to FIG. 5F, the second mask pattern 84 may be removed, then a first and second solder bump layers 48A and 48B may be formed by performing a reflow process to the first and second solder layers 47A and 47B. For example, the second mask pattern 84 may be removed by an ashing process, and the first and second solder bump layers 48A and 48B may be formed by reflowing the first and second solder layers 47A and 47B at a temperature in a range from about 200° C. to about 300° C. The first and second solder bump layers 48A and 48B may have bead shapes. A portion of the UBM layer 38, that is not covered by the base bump layer 40 and the second pillar bump layer 46B, may be removed by a wet etching, thereby forming a first UBM layer 38A on the conductive pad 30 on the first region SA and a second UBM layer 38B on the passivation layer 30 on the second region SB. The first UBM layer 38A may include a first barrier layer 34A and a first seed layer 36A, and the second UBM layer 38B may include a second barrier layer 34B and a second seed layer 36B. In some embodiments, after a portion of the UBM layer 38, that is not covered by the base bump layer 40 and the second pillar bump layer 46B, is removed by wet etching, the first and second solder layers 47A and 47B may be reflowed to form the first and second solder bump layers 48A and 48B.

The top surfaces of the first and second solder layers 47A and 47B are substantially coplanar, so top ends of the first and second solder bump layers 48A and 48B may be at substantially the same level. As illustrated in FIG. 1C, the first solder bump layer 48A may have a first maximum horizontal width 48AW1 in the first direction D1 and a second maximum horizontal width 48AW2 in the second direction D2. The first maximum horizontal width 48AW1 may be less than the second maximum horizontal width 48AW2. In some embodiments, the first maximum horizontal width 48AW1 and the second maximum horizontal width 48AW2 may be substantially same. As illustrated in FIG. 1C, the second solder bump layer 48B may have a first maximum horizontal width 48BW1 in the first direction D1 and a second maximum horizontal width 48BW2 in the second direction D2. The first maximum horizontal width 48BW1 may be less than the second maximum horizontal width 48BW2. In some embodiments, the first maximum horizontal width 48BW1 and the second maximum horizontal width 48BW2 may be substantially same. In other embodiments, a size of the second solder bump layer 48B may be substantially equal to, or less than that of the first solder bump layer 48A. Each of the first and second solder bump layers 48A and 48B may have a circular shape or an oval shape, when viewed in plan view.

In some embodiments, when the UBM layer 38 is removed by wet etching, a portion of the base bump layer 40 and a portion of each of the first and second pillar bump layers 46A and 46B may be etched.

As a result, a bump structure 50 including a first bump structure 50A and a second bump structure 50B may be formed on the semiconductor substrate 10. The first bump structure 50A may be formed on the first region SA, and the second bump structure 50B may be formed on the second region SB. The first bump structure 50A may include the base bump layer 40 including the base portion 40A and protrusion portion 40P, the first pillar bump layer 46A, and the first solder bump layer 48A that are sequentially stacked on the conductive pad 30. A portion of the first pillar bump layer 46A may be surrounded by the protrusion portion 40P of the base bump layer 40. A sidewall 46AS of the first pillar bump layer 46A may be opposed to the inner sidewall 40PS1 of the protrusion portion 40P. The second bump structure 50B may include the second pillar bump layer 46B and the second solder bump layer 48B that are sequentially stacked on the passivation layer 32. The first bump structure 50A may be an active bump structure that is electrically connected to the wires 28 (refer to the FIGS. 1E and 1F) of the integrated circuit layer 20. The second bump structure 50B may be separated or isolated from the conductive pad 30. Thus, the second bump structure 50B may be an inactive or dummy bump structure that is not electrically connected to the wires 28 (refer to the FIGS. 1E and 1F) of the integrated circuit layer 20. The first UBM layer 38A may be disposed between the first bump structure 50A and the conductive pad 30, and the second UBM layer 38B may be disposed between the second bump structure 50B and the passivation layer 32.

Therefore, the semiconductor device 110 including the first and second bump structures 50A and 50B as illustrated in FIGS. 1A-2D may be formed using above described processes. The bump structures 50 of the semiconductor device 110 may protect against corrosion of the conductive pads 30 because the conductive pads 30 may be isolated from the external environment by the base bump layer. In addition, since the bump structures 50 have top ends 52A and 52B that are at substantially the same level, bonding defects may be prevented or reduced to ensure the electrical connection between the semiconductor device and the package substrate or other electric devices, when the semiconductor device 110 is mounted on the package substrate 80. Thus, the semiconductor device 110 according to the embodiments of the inventive concepts may have a highly improved reliability.

Alternatively, a bump structure may include a base bump layer and a solder bump layer. The base bump layer includes a base portion and a protrusion portion as described above in associated with FIGS. 1A to 1D, and 2A to 2D. The base bump layer is formed as described in FIG. 5A to 5F. The solder bump layer may be formed as described in FIGS. 5A to 5F except that the first solder layer may be formed on the base bump layer, and the second solder layer may be formed on the UMB layer. The thickness of the base portion is configured to supplement a step difference between a top surface of the conductive pad and a top surface of the passivation layer such that a top end of the first bump structure and a top end of the second bump structure are at substantially the same level relative to a main surface of the substrate. Additionally when viewed in plan view, the area of each base bump layer is equal to or greater than the area of each corresponding conductive pad, which is exposed by the opening in the passivation layer, such that the conductive pads are covered substantially completely by the base bump layer and are isolated from the external environment.

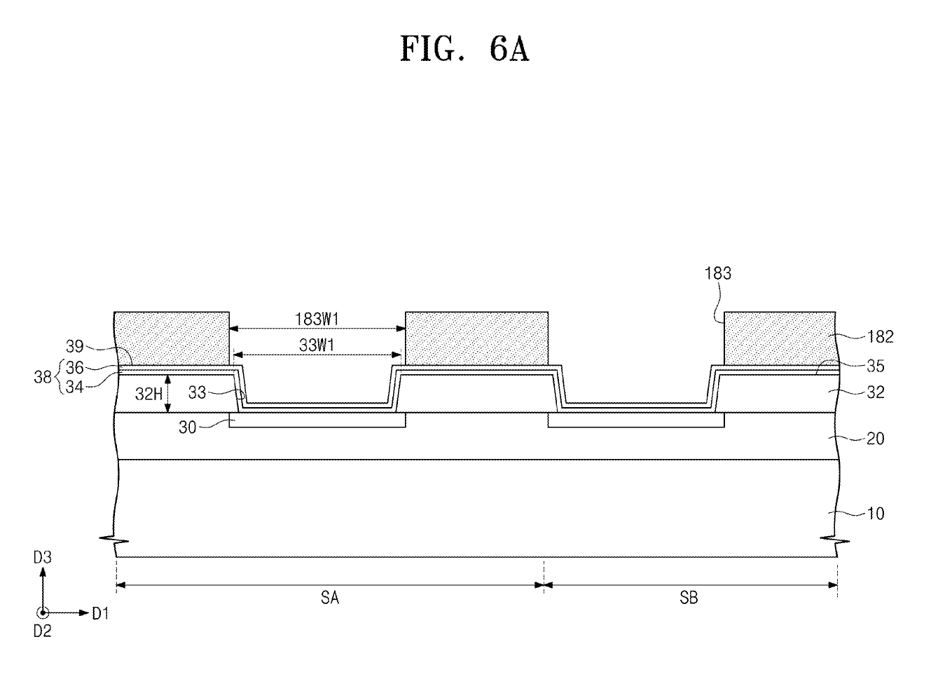

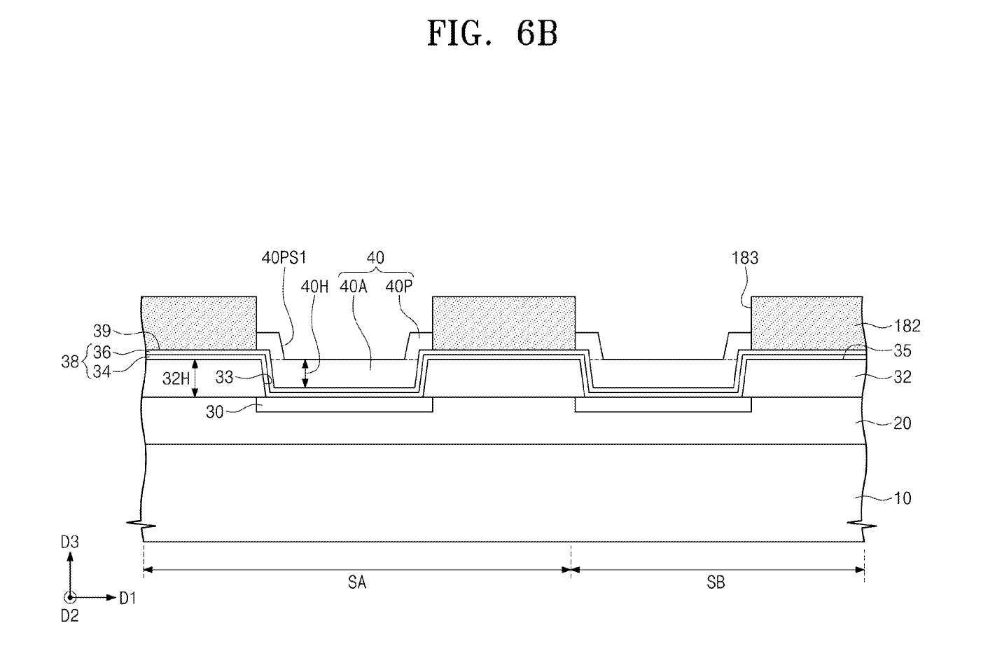

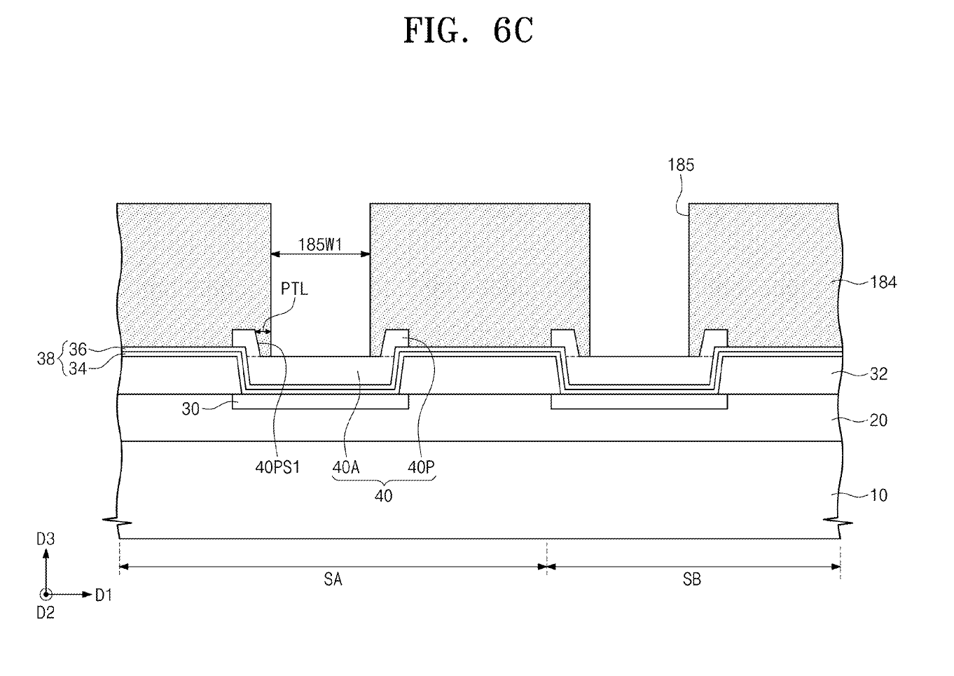

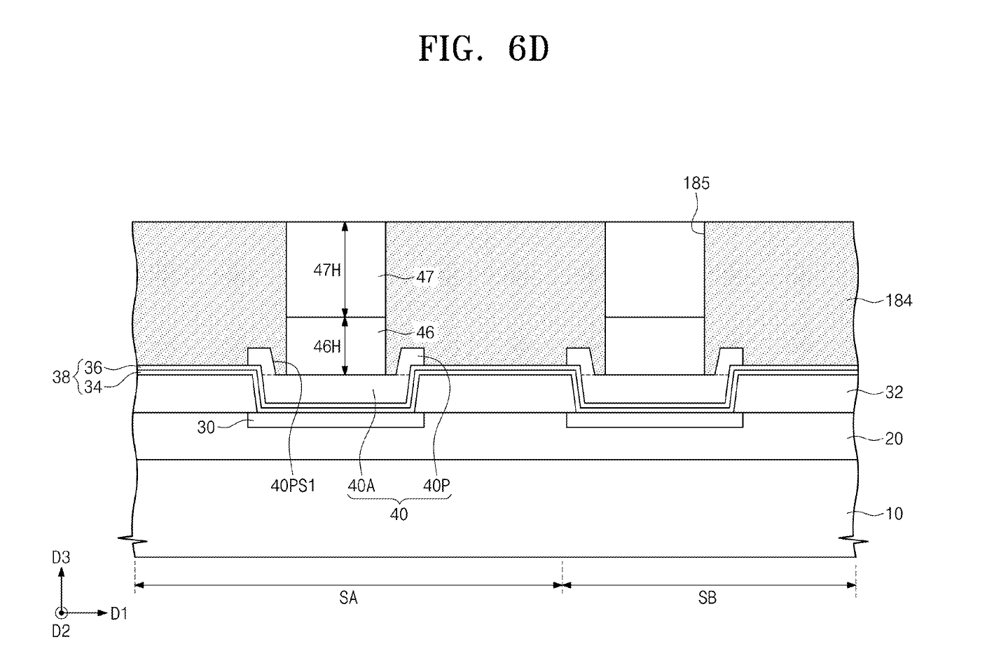

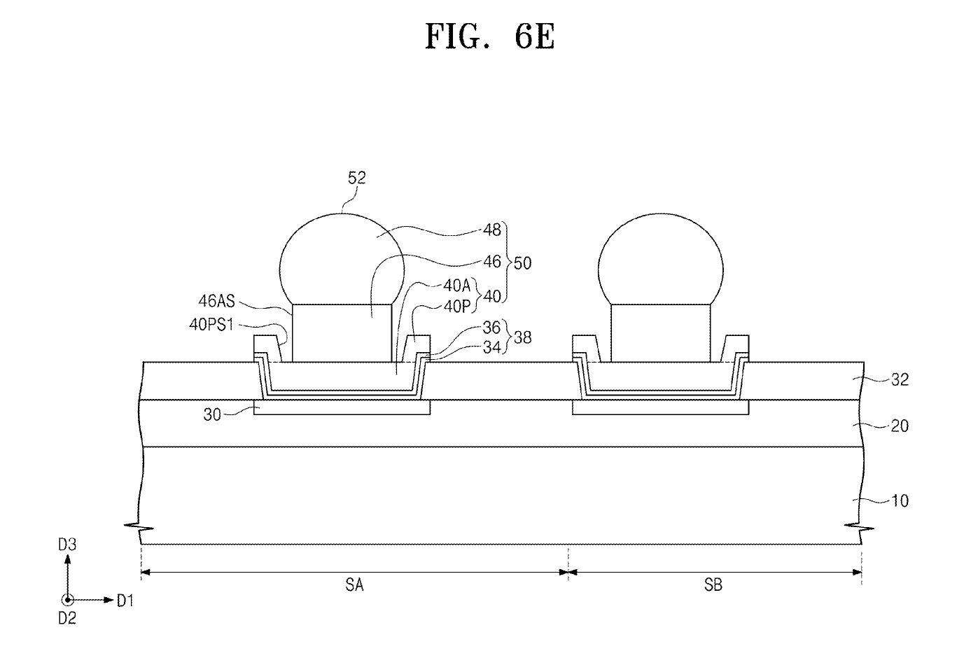

FIGS. 6A to 6E are cross-sectional views illustrating a method for fabricating a semiconductor device according to some example embodiments of the inventive concepts

Referring to FIG. 6A, an UBM layer 38 may be formed on the semiconductor substrate 10 that an integrated circuit layer 20, a conductive pad 30, and a passivation layer 32 including a first opening 33 are provided thereon. In some embodiments, at least one through-substrate via 70, penetrating the semiconductor substrate 10 and connected to the conductive pad 30, may be further formed, as shown in FIG. 1F.

The conductive pad 30 may be formed in a plurality on the semiconductor substrate 10. The conductive pad 30 may include copper or aluminum, for example. When viewed in plan view, the conductive pad 30 may have a tetragonal shape, a circular shape, or an oval shape.

The passivation layer 32 may cover the integrated circuit layer 20 and expose the conductive pad 30. For example, the passivation layer 32 may have the first opening 33 exposing the conductive pad 30. The first opening 30 may be formed by etching the passivation layer 32. The first opening 33 may have a positively sloped sidewall. The first opening 33 may have a first horizontal width 33W1 in the first direction D1. The first opening 33 may be similar in shape to the conductive pad 30, when viewed in plan view.

The passivation layer 32 may include a single layer or multi-layers. A thickness 32H of the passivation layer 32 may be, for example, about 2 μm to 5 μm. The passivation layer 32 may be a polymer layer or a dielectric layer, for example. The polymer layer may include a photosensitive material.

The UBM layer 38 may be formed conformally on the passivation layer 32 and in the first opening 30. The UBM layer 38 may include a barrier layer 34 and a seed layer 36 that are sequentially stacked on the conductive pad 30 and the passivation layer 32. The barrier layer 34 may have a thickness, for example, ranging from about 1000Å to 3000Å. The seed layer 36 may have a thickness, for example, ranging from about 2000Å to 5000Å. The barrier layer 34 may include, for example, Ti, Ti—W, Cr, or combinations thereof. The seed layer 36 may include Cu, Cu alloy, Ni, Ni alloy, or combinations thereof.

A first mask pattern 182 including a second opening 183 may be formed on the UBM layer 38 such that the second opening 83 overlaps with the first opening 33. The second opening 83 may be greater in size than the first opening 33. A horizontal width 183W1 of the second opening 183 may be greater than the first horizontal width 33W1 of the first opening 33. Thus, a portion of the seed layer 36 disposed in the first opening 33 and on the passivation layer 32 adjacent to the first opening 33 may be exposed by the second opening 183. The first mask pattern 182 may be formed by, for example, coating and patterning processes of a photoresist layer. The first mask pattern 182 may have a thickness, for example, ranging from about 1.5 μm to 10 μm.

Referring to FIG. 6B, a base bump layer 40 may be formed on the UBM layer 38. For example, the base bump layer 40 may be formed on the seed layer 36 using plating (e.g., electro plating, or electroless plating) process. The base bump layer 40 may fill at least a portion of the first opening 33 and extend upwardly along an inner sidewall of the second opening 183. Accordingly, the base bump layer 40 may include a base portion 40A that is in contact with the UBM layer 38 and fills at least a portion of the first opening 33, and a protrusion portion 40P that protrudes upwardly in the third direction D3 from an edge region of the base portion 40A. For example, the protrusion portion 40P may be disposed adjacent to an inner sidewall of the first opening 33. The protrusion portion 40P may be extended over a top surface 35 of the passivation layer 32 away from a center of the first opening 33 or may be extended over the top surface 39 of the UBM layer 38 away from the center of the first opening 33. The protrusion portion 40P may include a sloped inner sidewall PS1. The inner sidewall PS1 of the protrusion portion 40P may be positively sloped. The base bump layer 40 may have a thickness 40H, for example, ranging from about 1 μm to 5 μm. The thickness 40H of the base bump layer 40 may correspond to a thickness of the base portion 40P of the base bump layer 40. In some embodiments, thickness 40H of the base bump layer 40 may be substantially thinner than the thickness of the passivation layer 32, but the embodiments of the present disclosure are not limited thereto. For example, the thickness 40H of the base bump layer 40 may be the same as or greater than the thickness of the passivation layer 32. The base bump layer 40 may have a saucer shape in some embodiments. For example, the base bump layer 40 may have a circular saucer shape, an oval saucer shape, or a polygonal saucer shape such as a tetragonal saucer shape or an octagonal saucer shape. The base bump layer 40 may include metal (e.g., Cu, Cu alloy, Ni, Ni alloy, Au, Au alloy, or combinations thereof). The base bump layer 40 may cover fully the conductive pad 30 such that the conductive pad 30 is not exposed to an external environment.

Referring to FIG. 6C, the first mask pattern 182 may be removed, then the second mask pattern 184 exposing a portion of the base bump layer 40 may be formed on the semiconductor substrate 10. The first mask pattern 182 may be removed using an ashing process. The second mask pattern 184 may include a third opening 185 exposing a portion of the base bump layer 40. The second mask pattern 184 may be formed in such a way that an inner sidewall of the third opening 185 is spaced apart from the inner sidewall 40PS1 of the protrusion portion 40P of the base bump layer 40 by a maximum distance PTL. The maximum distance PTL may be, for example, about 1 μm to 3 μm. The second mask pattern 184 may be formed to cover the protrusion portion 40P of the base bump layer 40. A horizontal width 185W1 of the third opening 185 in the first direction D1 may be smaller than a horizontal width 183W1 of the second opening 183 in the first direction D1. The second mask pattern 184 may be formed by, for example, coating and patterning processes of a photoresist layer. When viewed in plan view, the third opening 185 may have a polygonal shape such as a tetragonal shape or an octagonal shape, a circular shape, or an oval shape.

Referring to 6D, a pillar bump layer 46 may be formed in the third opening 185. The pillar bump layer 46 may be formed on the base portion 40A of the base bump layer 40 and may be spaced apart from the protrusion portion 40P of the base bump layer 40. Thus, the horizontal width of the pillar bump layer 46 in the first direction D1 may be smaller than that of the base bump layer 40 in the first direction D1. The horizontal width of the pillar bump layer 46 in the first direction D1 may be smaller than the horizontal width 33W1 shown in FIG. 6A of the first opening layer 33 in the first direction D1. The pillar bump layers 46 may be formed using a plating (e.g., electro plating, electroless plating) process. The pillar bump layer 46 may fill a portion of the third opening 185. The pillar bump layer 46 may include metal (e.g., Cu, Cu alloy, Ni, Ni alloy, Au, Au alloy, or combinations thereof). A thickness 46H of the pillar bump layer 46 may be, for example, about 10 μm to 30 μm.

A solder layer 47 may be formed on the pillar bump layer 46. The solder layer 47 may fill the third opening 185. A thickness 47H of the solder layer 47 may be, for example, about 15μm to 60 μm. The solder layer 47 may be formed by a plating (e.g., electro plating, or electroless plating) process. The solder layer 47 may include a solder material. For example, the solder layer 47 may include Sn, Pb, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, Sn—Ag-Ce, or combinations thereof.

Referring to FIG. 6E, the second mask pattern 184 may be removed, and then a solder bump layer 48 may be formed by reflowing the solder layer 47. For example, the second mask pattern 184 may be removed by an ashing process, and the solder bump layer 48 may be formed by performing a reflow process to the first and second solder layers 47 at a temperature in a range from about 200° C. to about 300° C. Solder bump layers 48 may have a bead shape, for example. A portion of the UBM layer 38 that is not covered by the base bump layer 40 may be removed by a wet etching. In some embodiments, after a portion of the UBM layer 38 that is not covered by the base bump layer 40, is removed, the solder layer 47 may be reflowed to form the first and second solder bump layers 48.

As illustrated in FIG. 3C, the solder bump layer 48 may have a first maximum horizontal width 48W1 in the first direction D1 and a second maximum horizontal width 48W2 in the second direction D2. The first maximum horizontal width 48W1 may be smaller than the second maximum horizontal width 48W2. In some embodiments, the first maximum horizontal width 48W1 and the second maximum horizontal width 48W2 may be substantially same. The solder bump layer 48 may have a circular shape, or an oval shape, for example, in plan view. In some embodiments, when the UBM layer 38 is removed by wet etching, a portion of the base bump layer 40 and a portion of pillar bump layer may be etched.

As a result, a bump structure 50 may be formed on the semiconductor substrate 10. The bump structure 50 may be formed in a plurality on the semiconductor substrate 10. The bump structure 50 may include the base bump layer 40 including the base portion 40A and protrusion portion 40P, the pillar bump layer 46, and the solder bump layer 48 that are sequentially stacked on the conductive pad 30. A portion of the pillar bump layer 46 may be surrounded by the protrusion portion 40P of the base bump layer 40. A sidewall 46AS of the pillar bump layer 46 may be opposed to the inner sidewall 40PS1 of the protrusion portion 40P. The UBM layer 38 may be disposed between the bump structure 50 and the conductive pad 30.

Therefore, the semiconductor device 120 including the bump structures 50 as illustrated in FIGS. 3A to 3C, 4A, and B may be formed using above described processes. The bump structures 50 of the semiconductor device 120 may protect against corrosion of the conductive pads 30 as the conductive pads 30 are isolated from the external environment. In addition, since each of the bump structures 50 have top ends 52 that are at substantially the same level or at substantially the same plane, bonding defects may be prevented or reduced, when the semiconductor device 120 is mounted on the package substrate 80. Thus, the semiconductor device 120 according to some embodiments of the inventive concepts may have a highly improved reliability.

Alternatively, a bump structure may include a base bump layer and a solder bump layer. The base bump layer includes a base portion and a protrusion portion as described above in associated with FIGS. 3A to 3C, 4A and 4B. The base bump layer may be formed as described in FIGS. 6A to 6E. The solder bump layer may be formed as described in FIGS. 6A to 6E except that the first solder layer may be formed on the first base bump layer, and the second solder layer may be formed on the second base bump layer. The thickness of the base portion may be configured to supplement a step difference between a top surface of the first conductive pad and a top surface of the second conductive pad such that a top end of the first bump structure and a top end of the second bump structure are at substantially the same level relative to a main surface of the substrate. Additionally when viewed in a plan view, the area of each base bump layer is equal to or greater than the area of each corresponding conductive pad, which is exposed by the opening in the passivation such that the conductive pads are covered substantially completely by the base bump layer and are isolated from the external environment.

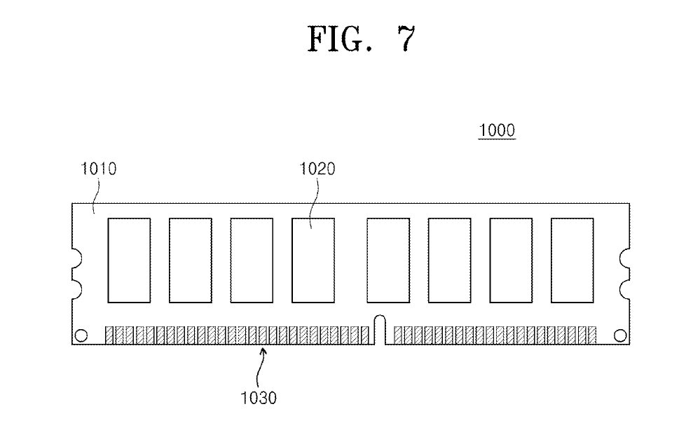

FIGS. 7 is a schematic block diagram illustrating an example of memory module including at least one of the semiconductor devices and/or the semiconductor packages according to some example embodiments of the inventive concepts.

Referring to FIG.7, a memory module 1000 may include a module substrate 1010 and a memory device 1020 on the module substrate 1010. The memory device 1020 may include at least one of the semiconductor devices and/or the semiconductor packages according to example embodiments of the inventive concepts. Input/output terminals 1030 may be disposed at least one side of the module substrate 1010.

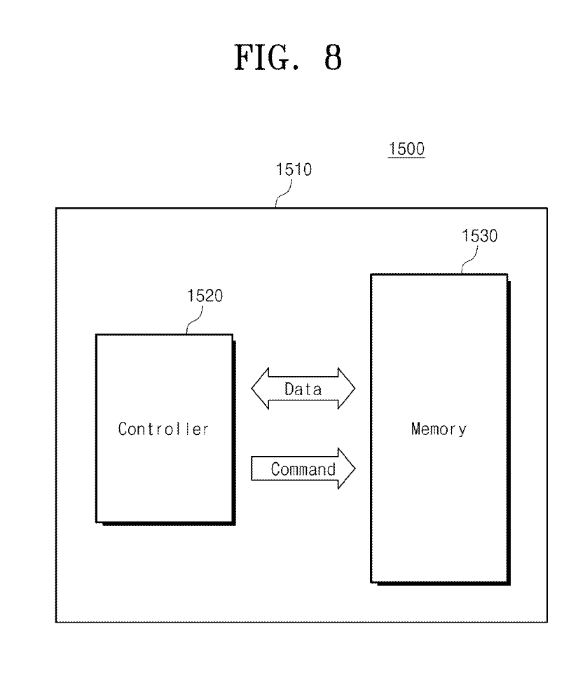

FIG. 8 is a schematic block diagram illustrating an example of memory system including at least one of the semiconductor devices and/or the semiconductor packages according to example embodiments of the inventive concepts.

Referring to FIG. 8, a memory system 1500 may be configured to store data in at least one semiconductor device. For example, the memory system 1500 may be provided in the form of a memory card or a solid state drive (SSD). The memory system 1500 may include a controller 1520 and a memory device 1530 provided in a housing 1510. The memory system 1500 may be configured to allow electric signals to be exchanged between the controller 1520 and the memory device 1530. For example, an operation of exchanging data between the memory device 1530 and the controller 1520 may be executed in response to commands from the controller 1520. In other words, the memory system 1500 may be configured to store data in the memory device 1530 or send data stored in the memory device 1530 to the outside thereof. The memory device 1530 may include one of the semiconductor devices and/or the semiconductor packages according to example embodiments of inventive concepts.

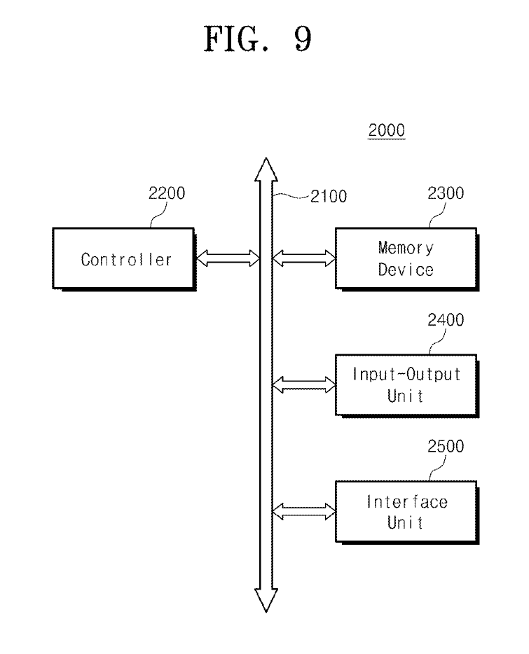

FIG. 9 is a schematic block diagram illustrating an example of an electronic system including at least one of the semiconductor devices and/or the semiconductor packages according to example embodiments of the inventive concepts.

Referring to FIG. 9, an electronic system 2000 may include a controller 2200, a memory device 2300, and an input-output unit 2400. The controller 2200, the memory device 2300, and the input-output unit 2400 may be electrically coupled or connected to each other via a bus 2100. The bus 2100 may correspond to a path through which electrical signals or data are transmitted. The controller 2200 may include at least one of a microprocessor, a digital signal processor, a microcontroller, or a logic device. The logic device may have a similar function to any one of the microprocessor, the digital signal processor and the microcontroller. The input-output unit 2400 may include at least one of a keypad, a keyboard, or a display device. The memory device 2300 may store data and/or commands executed by the controller 2200. The memory device 2300 may include a volatile memory device and/or a nonvolatile memory device. For example, the memory device 2300 may include a DRAM or a FLASH memory device. Alternatively, the memory device 2300 may include a solid state drive (SSD) including at least one FLASH memory device, and in this case, the electronic system 2000 may stably store a large capacity of data. In example embodiments, the memory device 2300 may include at least one of the semiconductor devices or the semiconductor packages according to example embodiments of inventive concepts. The electronic system 2000 may further include an interface unit 2500 for transmitting or receiving data to or from a communication network through a wireless or wired way. For example, the interface unit 2500 may include an antenna for wireless communication or a transceiver for wired communication.

According to example embodiments of inventive concepts, the bump structure including a base bump layer covering a conductive pad is provided, and this bump structure makes it possible to substantially prevent the conductive pad from the corrosion caused by chemicals and/or moisture. Thus, a semiconductor device with highly improved reliability can be embodied. Further, the difference in level between a top end of the active bump structure on the conductive pad and a top end of the dummy bump structure on the passivation layer or the difference in level between top ends of a plurality of active bump structures on the conductive pad is supplemented by the base bump layer. Accordingly, it is possible to prevent the bonding defects, when the semiconductor device is mounted on the package substrate 80. As a result, it is possible to realize a semiconductor package with improved reliability, and increased yields.

While example embodiments of inventive concepts have been described in connection with the embodiment of the present invention illustrated in the accompanying drawings, it will be understood by one of ordinary skill in the art that variations in form and detail may be made therein without departing from the spirit and scope of the claims.

1. A semiconductor device, comprising:
a semiconductor substrate;
a conductive pad on the semiconductor substrate;
a passivation layer on the semiconductor substrate, the passivation layer including an opening exposing the conductive pad;
a first under bump metal (UBM) layer on the exposed conductive pad, and a second under bump metal (UBM) layer on the passivation layer;
a first bump structure on the first UBM layer, the first bump structure including a base bump layer, a first pillar bump layer, and a first solder bump layer sequentially stacked on the first UBM layer; and
a second bump structure on the second UBM layer, the second bump structure including a second pillar bump layer and a second solder bump layer sequentially stacked on the second UBM layer.

2. The semiconductor device of claim 1, wherein each of horizontal widths of the opening and the base bump layer is greater than a horizontal width of the first pillar bump layer.

3. The semiconductor device of claim 1, wherein the base bump layer comprises a base portion underneath the first pillar bump layer and a protrusion portion spaced apart from the first pillar bump layer.

4. The semiconductor device of claim 3, wherein the base portion fills at least a portion of the opening.

5. The semiconductor device of claim 3, wherein the protrusion portion is disposed adjacent to an inner sidewall of the opening and surrounds the first pillar bump layer.

6. The semiconductor device of claim 4, wherein the protrusion portion comprises a sloped inner sidewall opposed to a sidewall of the first pillar bump layer.

7. The semiconductor device of claim 1, wherein the first pillar bump layer has a thickness substantially identical to that of the second pillar bump layer.

8. The semiconductor device of claim 1, wherein a top end of the first bump structure and a top end of the second bump structure are positioned at substantially a same level relative to a main surface of the semiconductor substrate.

9. The semiconductor device of claim 1, wherein the first and second pillar bump layers include a same metal, and the first and second solder bump layers include a same solder material.

10. The semiconductor device of claim 1, wherein a horizontal width of the first pillar bump layer is greater than that of the second pillar bump layer.

11. The semiconductor device of claim 1, wherein the first pillar bump layer has a shape different from the second pillar bump layer, in plan view.

12. The semiconductor device of claim 1, wherein each of the base bump layer and the first pillar bump layer includes Cu, Cu alloy, Ni, Ni alloy, Au, Au alloy, or combinations thereof.

13. The semiconductor device of claim 1, further comprising at least one through-substrate via (TSV) penetrating the semiconductor substrate and connected to the conductive pad.

14-22. (canceled)

23. A semiconductor package, comprising:
a package substrate including first and second substrate pads disposed thereon; and
a semiconductor device mounted on the package substrate, the semiconductor device including a semiconductor substrate, a conductive pad on the semiconductor substrate, a passivation layer on the semiconductor substrate with an opening exposing the conductive pad, a first bump structure coupled to the first substrate pad of the package substrate, and a second bump structure coupled to the second substrate pad of the package substrate;
wherein the first bump structure includes a base bump layer, a first pillar bump layer, and a first solder bump layer that are sequentially stacked on the conductive pad, and
wherein the second bump structure includes a second pillar bump layer and a second solder bump layer that are sequentially stacked on the passivation layer.

24. The semiconductor package of claim 23, wherein the base bump layer includes a base portion underneath the first pillar bump layer, and a protrusion portion adjacent to the an inner sidewall of the opening and spaced apart from the first pillar bump layer.

25. The semiconductor package of claim 24, wherein the protrusion portion comprises a sloped inner sidewall opposed to a sidewall of the pillar bump layer.

26. The semiconductor package of claim 23, wherein each of horizontal widths of the opening and the base bump layer is greater than a horizontal width of the first pillar bump layer.

27. The semiconductor package of claim 23, wherein thicknesses of the first and second pillar bump layers are substantially same.

28. The semiconductor package of claim 23, wherein the semiconductor device further comprises a first under bump metal (UBM) layer disposed between the conductive pad and the base portion of the base bump layer, and a second under bump metal (UBM) layer disposed between the passivation layer and the second pillar bump layer.

29. The semiconductor package of claim 23, wherein the semiconductor device further comprises a through-substrate via (TSV) penetrating the semiconductor substrate and connected to the conductive pad,

30. The semiconductor package of claim 23, wherein the semiconductor substrate includes a central region and a peripheral region, and
wherein the first bump structure is disposed on the central region, and the second bump structure is disposed on the peripheral region.

31. A semiconductor package, comprising:
a package substrate including a substrate pad; and
a semiconductor device mounted on the package substrate, the semiconductor device including:
a semiconductor substrate;
a conductive pad on the semiconductor substrate;
a passivation layer on the semiconductor substrate, the passivation layer including an opening exposing the conductive pad;
a under bump metal (UBM) layer on the conductive pad, the UBM layer disposed in the opening;
a base bump layer on the UBM layer, the base bump layer including a base portion filling at least a portion of the opening, and a protrusion portion extending upwardly from the base portion;
a pillar bump layer on the base portion, the pillar bump layer being spaced apart from the protrusion portion;
a solder bump layer on the pillar bump layer, the solder bump layer bonded to the substrate pad of the package substrate.

32. The semiconductor package of claim 31, wherein each of horizontal widths of the opening and the base bump layer is greater than a horizontal width of the pillar bump layer.

33. The semiconductor package of claim 31, wherein the protrusion portion is disposed adjacent to an inner sidewall of the opening and surrounds a portion of the pillar bump layer.

34. The semiconductor package of claim 31, wherein the protrusion portion comprises a sloped inner sidewall opposed to a sidewall of the pillar bump layer.

35-48. (canceled)
